(19) United States
(12) Patent Application Publication
(10) Pub. No.: US 2016/0353070 A1
(43) Pub. Date: Dec. 1, 2016

(54) LIGHT SOURCE DEVICE AND PROJECTOR

(71) Applicant: USHIO DENKI KABUSHIKI KAISHA, Tokyo (JP)

(72) Inventors: Masashi OKAMOTO, Himeji-shi (JP); Takanori SAMEJIMA, Himeji-shi (JP); Fumihiko ODA, Himeji-shi (JP)

(73) Assignee: USHIO DENKI KABUSHIKI KAISHA, Tokyo (JP)

(21) Appl. No.: 15/117,379

(22) PCT Filed: Feb. 26, 2015
(86) PCT No.: PCT/JP2015/055664

§ 371 Date: Aug. 8, 2016

(30) Foreign Application Priority Data
Feb. 27, 2014 (JP) 2014-036997

(51) Int. Cl. H04N 9/31; H01S 5/042; H05B 37/02

(52) U.S. Cl. CPC H04N 9/3182; H04N 9/3155; H04N 9/3158; H04N 9/3194; H04N 9/3164; H04N 9/3161; H05B 37/029; H05B 37/0227; H01S 5/042

(57) ABSTRACT

The light source device is provided with a plurality of light emitting elements including light emitting elements whose emission wavelength belongs to a plurality of types of different wavelength bands, band light characteristics acquisition means generating band light characteristics acquisition data for each wavelength band, and an integrating control circuit generating a color phase instruction value and performing feedback control of a drive circuit of the light emitting element such that a difference between the color phase instruction value and the target value thereof is reduced. The integrating control circuit obtains, through an interface section, color phase correlation data correlated with a color phase instruction value with respect to the result of applying the output luminous flux to an external apparatus using the light source device and updates a target value of the color phase instruction value with the use of the color phase correlation data.

### TECHNICAL FIELD

The present invention relates to a light source device, which is usable in an optical apparatus such as a projector and uses a light emitting element, such as a semiconductor laser, belonging to a plurality of types of different wavelength bands, and a projector provided with the light source device.

### BACKGROUND ART

For example, in a projector for image display, such as a DLP (TM) projector and a liquid crystal projector, and a photomask exposure apparatus, a high intensity discharge lamp (an HID lamp) such as a xenon lamp and a super-high pressure mercury lamp has been used.

As an example, a principle of a projector is described using FIG. 9 (see JP-A-2004-252112, etc.). FIG. 9 is a view for explaining one embodiment of a portion of one type of conventional projector according to the projector of the present invention.

As described above, light from a light source (SjA) formed of a high intensity discharge lamp or the like enters an incident end (PmiA) of light uniformizing means (FmA) with the help of focusing means (illustration thereof is omitted) formed of a concave reflector, lens, or the like, and the entering light is output from an emission end (PmoA).

Here, for example, an optical guide may be used as the light uniformizing means (FmA). The optical guide is also called by a name such as a rod integrator or a light tunnel, and may be constituted of a rectangular cylinder formed of a light transmissive material such as glass or resin. In such an optical guide, light input to the incident end (PmiA) propagates inside the light uniformizing means (FmA) while repeatedly being totally reflected by side faces of the light uniformizing means (FmA) in accordance with a same principle as that of an optical fiber. This achieves a function of sufficiently uniformizing illuminance on the emission end (PmoA) even when distribution of the light input to the incident end (PmiA) is non-uniform.

Incidentally, regarding the optical guide described above, in addition to the above-described optical guide constituted of a rectangular cylinder formed of a light transmissive material such as glass or resin, there is an optical guide which is constituted of a hollow rectangular cylinder having inner faces being reflectors, causes light to propagate therein while, similarly, repeatedly reflecting the light with the inner faces, and thereby achieves a similar function.

When an illumination lens (Ej IA) is disposed such that a square image of the emission end (PmoA) is formed on a two-dimensional optical amplitude modulation element (DmjA), the two-dimensional optical amplitude modulation element (DmjA) is illuminated with the light output from the emission end (PmoA). However, in FIG. 9, a mirror (MjA) is disposed between the illumination lens (Ej IA) and the two-dimensional optical amplitude modulation element (DmjA).

Then, the two-dimensional optical amplitude modulation element (DmjA) directs the light to a direction entering an image projection lens (Ej2A) for each pixel, according to a video signal, or the two-dimensional optical amplitude modulation element (DmjA) modulates the light to direct the light to a direction not entering the image projection lens (Ej2A) for each pixel and, thus, to display an image on a screen (Tj)

Note that the two-dimensional optical amplitude modulation element (DmjA) as described above is also called light bulb, and in the case of the optical system of FIG. 9, DMD (Digital micro-mirror device) (TM) is generally often used as the two-dimensional optical amplitude modulation element (DmjA).

Regarding the light uniformizing means, in addition to the above-described optical guide, there is light uniformizing means called a fly eye integrator. As an example, a principle of a projector using this light uniformizing means is described using FIG. 10 (see JP-A-2001-142141, etc.). FIG. 10 is a view for explaining one embodiment of a portion of one type of conventional projector according to the projector of the present invention.

Light from a light source (SjB) constituted of a high intensity discharge lamp or the like enters, as substantially parallel luminous flux, an incident end (PmiB) of the light uniformizing means (FmB) formed of a fly eye integrator with the help of collimator means (illustration thereof is omitted) formed of a concave reflector, lens, or the like, and the entering light is output from an emission end (PmoB). Here, the light uniformizing means (FmB) is configured by combination of a front fly eye lens (F1B) on incident side, a rear fly eye lens (F2B) on exit side, and an illumination lens (Ej1B).

Each of the front fly eye lens (F1B) and the rear fly eye lens (F2B) is formed by vertically and horizontally arranging many square lenses having the same focal length and the same shape.

Each of the front fly eye lenses (F1B) and the corresponding lens of the rear fly eye lens (F2B) on the rear stages of the corresponding front fly eye lenses constitute an optical system called a Kohler illumination optical system, and many Kohler illumination optical systems are accordingly arranged vertically and horizontally.

Typically, Kohler illumination optical system is constituted of two lenses. When this optical system collects light with a front lens to illuminate a target surface, the two lenses are disposed such that the front lens forms a light source image not on the target surface but on a surface of a center of a rear lens, and the rear lens forms an image of a square of an outer shape of the front lens on the target surface (a surface desired to be illuminated), whereby the target surface is uniformly illuminated.

In a case where the rear lens is not provided, when the light source is not a complete point light source but has a finite size, there occurs a phenomenon in which illuminance in the periphery of the square on the target surface is dropped depending on the size. However, the rear lens allows uniform illuminance over to the periphery of the square on the target surface without depending on the size of the light source.

Here, in the case of the optical system in FIG. 10, since substantially parallel luminous flux is basically input to the light uniformizing means (FmB), the front fly eye lens (F1B) and the rear fly eye lens (F2B) are disposed such that a distance therebetween becomes equal to the focal length thereof, and thus, an image on the target surface of uniform illumination as Kohler illumination optical system is generated to the infinity. Incidentally, since the illumination lens (Ej1B) is disposed on a rear stage of the rear fly eye lens (F2B), the target surface is drawn on a focal plane of the illumination lens (Ej1B) from the infinity.

Each of the many Kohler illumination optical systems arranged vertically and horizontally is parallel to an incident optical axis (ZiB), and a luminous flux is input to each of the Kohler illumination optical systems substantially axisymmetrically to the center axis thereof. Therefore, output luminous flux is also axisymmetrical. Thus, images of the outputs of all of the Kohler illumination optical systems are formed on the same target surface on the focal plane of the illumination lens (Ej1B) by property of the lens in which light beams entering a lens surface at the same angle are refracted to travel toward the same point on the focal plane irrespective of incident positions of the respective light beams on the lens surface, namely, Fourier transform function of the lens.

As a result, illumination distributions on the respective lens surfaces of the front fly eye lenses (F1B) are all overlapped, and thus a synthesized square image whose illuminance distribution is more uniform than that in the case of one Kohler illumination optical system is formed on the incident optical axis (ZiB).

When the two-dimensional optical amplitude modulation element (DmjB) is disposed on the position of the synthesized square image, the two-dimensional optical amplitude modulation element (DmjB) serving as an illumination target is illuminated with light output from the emission end (PmoB). Incidentally, in the illumination, a polarization beam splitter (MjB) is disposed between the illumination lens (Ej1B) and the two-dimensional optical amplitude modulation element (DmjB) to reflect the light toward the two-dimensional optical amplitude modulation element (DmjB).

Then, the two-dimensional optical amplitude modulation element (DmjB) modulates the light and reflects the modulated light such that the polarization direction of light for each pixel is rotated by 90 degrees or is not rotated, according to a video signal, whereby only the rotated light passes through the polarization beam splitter (MjB) and enters an image projection lens (Ej3B), thereby displaying an image on the screen (Tj).

In the case of the optical system in FIG. 10, LCOS (TM) (silicon liquid crystal device) is commonly often used as the two-dimensional optical amplitude modulation element (DmjB).

In the case of such a liquid crystal device, since only a component of light in a specified polarization direction is effectively modulated, a polarization aligning function element (PcB) is usually interposed, for example, on a rear stage of the rear fly eye lens (F2B). In the polarization aligning function element (PcB), although a component of light parallel to the specified polarization direction is transmitted without being modulated, polarization direction of only a component of light perpendicular to the specified polarization direction is rotated by 90 degrees, so that all of light can be effectively used.

In addition, for example, a field lens (Ej2B) may be interposed immediately before the two-dimensional optical amplitude modulation element (DmjB) so that substantially parallel light enters the two-dimensional optical amplitude modulation element (DmjB).

Incidentally, regarding a two-dimensional optical amplitude modulation element, in addition to the reflective two-dimensional optical amplitude modulation element illustrated in FIG. 10, a transmissive liquid crystal device (LCD) is used to have an optical arrangement adopted therein (see JP-A-10-133303, etc.).

Incidentally, in a typical projector, to perform color display of an image, for example, a dynamic color filter such as a color wheel is disposed on the rear stage of the light uniformizing means to illuminate the two-dimensional optical amplitude modulation element with color sequential luminous fluxes of R, G, and B (red, green, and blue), and color display is achieved time-divisionally. Alternatively, a dichroic mirror or a dichroic prism is disposed on the rear stage of the light uniformizing means to illuminate the two-dimensional optical amplitude modulation element that is provided independently for each color, with light color-separated to three primary colors of R, G, and B, and a dichroic mirror or a dichroic prism is disposed to configure an optical system for performing color synthesis of the modulated luminous fluxes of the three primary colors of R, G, and B. However, to avoid complication, an optical member for performing color display of an image is omitted in FIGS. 9 and 10.

However, the above-described high intensity discharge lamp has disadvantages such as low conversion efficiency from supplied power to optical power, that is, large heating loss, short life, or the like.

As an alternate light source overcoming these disadvantages, a solid light source such as an LED and a semiconductor laser has attracted attention in recent years.

Among them, in the LED, as compared with the discharge lamp, the heating loss is small, and the life is long. However, since light emitted from the LED does not have directivity similarly to the discharge lamp, there is a problem that usage efficiency of light is low in an application capable of using only light in a certain direction, such as the above-described projector and an exposure apparatus.

On the other hand, the semiconductor laser has a disadvantage that speckle occurs due to high coherency, but the disadvantage can be overcome by various technical improvements such as usage of a diffuser plate. Accordingly, in the semiconductor laser, similarly to LED, the heating loss is small, the life is long, and in addition, the directivity is high. Therefore, the semiconductor laser has an advantage that usage efficiency of light is high in the application capable of using only light in a certain direction, such as the above-described projector and an exposure apparatus.

Moreover, in the semiconductor laser, optical transmission can be performed with high efficiency through an optical fiber while utilizing the high directivity, and therefore, the installation position of the semiconductor laser can be separated from the position of a projector or the like using the light, so that flexibility of device designing can be enhanced.

The above-described high intensity discharge lamp has an advantage that a stable luminous flux of an emission spectrum can be always obtained only by inputting predetermined power to turn on the discharge lamp, since luminous fluxes of the three primary colors of R, G, and B are taken from a single lamp, and, in addition, since due to a very high plasma temperature of the discharge lamp, a luminous phenomenon is not affected by a little change in an environmental temperature.

However, since a semiconductor laser is required to be operated at a low temperature close to a room temperature, the light emission intensity varies due to an environmental temperature change or deterioration accompanying an increase of accumulated energization time. Accordingly, when semiconductor lasers as light sources of a projector are used in some or all of the three primary colors of R, G, and B, since the intensity of luminous fluxes of colors emitted by the semiconductor lasers is independent of the intensity of luminous fluxes from light sources of other colors, an intensity balance between the three primary colors is required to be made by active control and adjustment of a light source device, and, moreover, the problem that the intensity balance is disrupted by a change in conditions such as the environmental temperature and the accumulated energization time as described above is required to be solved.

In addition, since an emission wavelength may vary due to a change in the environmental temperature or deterioration accompanying an increase of accumulated energization time, when the semiconductor laser is applied to a highly faithful projector, stabilization of color, that is, stabilization of white balance and stabilization of brightness are required.

However, it can be considered that there is an advantage in that when semiconductor lasers are used in some or all of the three primary colors of R, G, and B, the intensity balance between the three primary colors is required to be made by active control and adjustment of the light source device as described above.

For example, since a xenon lamp among high intensity discharge lamps has a white light emission spectrum like sunlight, the xenon lamp has been often used as a light source of a projector for cinema. However, in the projector using the xenon lamp as the light source, if light usage efficiency of an optical system of the projector is low in a specific color, for example, B color, a desired balance between R, G, and B is required to be obtained by intentionally lowering the light usage efficiency of other colors, that is, discarding light partially.

On the other hand, when the semiconductor laser is used, the intensity of a luminous flux of the color of the semiconductor laser can be set independently of other colors. Thus, light emission is generated while considering that a balance of a spectrum of the light source device is intentionally eliminated from white color such that light of color in which the light usage efficiency of the optical system of the projector is low is strong, light of color in which the light usage efficiency is high is weak. Consequently, light to be discarded can be eliminated, and the semiconductor laser has a feature that can enhance the light usage efficiency as a whole.

However, previously, in particular in a projector for cinema, a xenon lamp is removed from a projector for cinema designed premising that the xenon lamp is used as the light source, and only a projector for cinema which receives an input of light from a light source device using a semiconductor laser instead of the xenon lamp to display a video and which is used for experiment or demonstration is manufactured. Thus, the above-described feature is not effectively used.

Moreover, in the experiment or demonstration, a color balance between R, G, and B has been adjusted by trial and error such that color of a video projected by a projector becomes desired color.

When a semiconductor laser or an LED is applied as a light source, a phenomenon occurs in which a color balance is disrupted by use conditions or an emission wavelength varies. A technique for avoiding conventional problems has been developed against this phenomenon.

For example, JP-A-2007-156211 discloses a technique in which in an apparatus which makes light sources of R, G, and B colors emit light in a color sequential manner, a spectral sensitivity distribution of an optical sensor of each of R, G, and B colors is considered as being the same as a color matching function in an XYZ color system established by CIE (International Commission of Illumination), and control is performed to reduce an error from a target value of output of each optical sensor, thereby correcting a white balance.

However, when feedback control of the white balance is performed, it has been unresolved how power supplied to respective light sources of three colors should be changed in order to converge on a target value.

For example, JP-A-2008-134378 discloses a technique in which an angle of a dichroic mirror is changed based on an output from an LED light source and a detection result of a light detection sensor detecting color, and an undesirable wavelength component is discarded from light emission from an LED to correct color. However, in such a technique, undesirable light is discarded, and thus it is low efficient. Moreover, a method of achieving the light detection sensor detecting color has been unresolved.

### PRIOR ART DOCUMENTS

### Patent Documents

Patent Document 1: JP-A-2007-156211

Patent Document 2: JP-A-2008-134378

### SUMMARY OF THE INVENTION

### Problems to be Solved by the Invention

An object to be achieved by the present invention is to provide a light source device, which quantitatively measures a color phase of an output luminous flux so that even if light usage efficiency for each wavelength band in a rear optical system, such as a projector, is not uniform, a desired color balance of output light of the rear optical system can be achieved, and can set and maintain a target color phase by feedback control, and a projector.

### Means for Solving the Problems

A light source device of the first invention according to the present invention is a light source in which a unit comprising a light emitting element (Y1a, Y1b, . . . ) emitting light in a narrow wavelength band and a drive circuit (P1a, P1b, . . . ) driving the light emitting element (Y1a, Y1b, . . . ) is a single elemental light source (U1, U2, . . . ) and which has a plurality of the elemental light sources (U1, U2, . . . ) and an integrating control circuit (Mc) controlling the drive circuit (P1a, P1b, P2a, P2b, . . . ) and emits an output luminous flux (Fo, Fo1, Fo2, . . .), obtained by gathering light emitted from the light emitting element (Y1a, Y1b, . . . , Y2a, Y2b, . . . ), to outside.

The light emitting element (Y1a, Y1b, Y2a, Y2b, . . . ) includes light emitting elements whose emission wavelength belongs to a plurality of types of different wavelength bands.

The light source device further has band light characteristics acquisition means (AiR, AiG, AiB) for receiving light of a quantity correlated with a light quantity of an integrated output luminous flux (Fo, Fo1, Fo2, . . . ) of the output luminous flux (Fo, Fo1, Fo2, . . . ) to generate band light characteristics acquisition data (ShR, ShG, ShB) for obtaining a light emission intensity instruction value correlated with light intensity for each of the wavelength bands and an interface section (If) for obtaining data from outside.

The integrating control circuit (Mc) at least intermittently obtains the band light characteristics acquisition data (ShR, ShG, ShB) generated by the band light characteristics acquisition means (AiR, AiG, AiB) to generate the light emission intensity instruction value and, at the same time, generates a color phase instruction value correlated with color of integrated light of the output luminous flux (Fo, Fo1, Fo2, . . . ) and determines variation of the light emission intensity instruction values for the respective wavelength bands to perform feedback control of the drive circuit (P1a, P1b, P2a, P2b, . . . ) such that a difference between the color phase instruction value and the target value thereof is reduced.

The integrating control circuit (Mc) can further execute an external data acquisition mode in which color phase correlation data (Se) correlated with the color phase instruction value with respect to the result of applying the output luminous flux (Fo, Fo1, Fo2, . . . ) to an external apparatus using the light source device is obtained through the interface section (If), and the integrating control circuit (Mc) updates a target value of the color phase instruction value with the use of the color phase correlation data (Se) after termination of the external data acquisition mode.

In a light source device of the second invention according to the present invention, a balance of light usage efficiency of an external apparatus using the light source device to each wavelength band is estimated by the color phase instruction value with respect to the result of applying the output luminous flux (Fo, Fo1, Fo2, . . . ) to an external apparatus using the light source device, the color phase instruction value being calculated from the color phase correlation data (Se) obtained by execution of the external data acquisition mode. After the estimation of the balance of the light usage efficiency of the external apparatus, the target value of the color phase instruction value of the light source device is set such that the color phase instruction value relating to the result of applying the output luminous flux (Fo, Fo1, Fo2, . . . ) to the external apparatus using the light source device approaches the color phase instruction value desired.

In a light source device of the third invention according to the present invention, the band light characteristics acquisition means (AiR, AiG, AiB) is configured to generate, in addition to the light emission intensity instruction value correlated with light intensity, the band light characteristics acquisition data (ShR, ShG, ShB) for obtaining a wavelength deviation instruction value correlated with deviation from reference wavelength for each of the wavelength bands. The integrating control circuit (Mc) obtains the band light characteristics acquisition data (ShR, ShG, ShB) from the band light characteristics acquisition means (AiR, AiG, AiB) to generate the wavelength deviation instruction value in addition to the light emission intensity instruction value. When generating the color phase instruction value, the integrating control circuit (Mc) holds, for each of the wavelength bands, local band color matching function information, including a function value in reference wavelength and the rate of function varying against wavelength varying, that is, gradient of a function value varying at the time of wavelength varying, with respect to the color matching functions required for calculation of chromaticity and calculates the color phase instruction value by a quantity correlated with chromaticity coordinates with the use of the wavelength deviation instruction value and the local band color matching function information for each of the wavelength bands.

In a light source device of the fourth invention according to the present invention, regarding spectral sensitivity characteristics of a light quantity detector provided for each of the wavelength bands for obtaining a light emission intensity instruction value correlated with light intensity in the band light characteristics acquisition means (AiR, AiG, AiB), a sensitivity value at reference wavelength determined in each of the wavelength bands and the rate of sensitivity varying against wavelength varying match with a sensitivity value at reference wavelength of three color matching functions of an XYZ color system and the rate of sensitivity varying against wavelength varying.

In a light source device of the fifth invention according to the present invention, regarding spectral sensitivity characteristics of a light quantity detector provided for each of the wavelength bands for obtaining a light emission intensity instruction value correlated with light intensity in the band light characteristics acquisition means (AiR, AiG, AiB), a sensitivity value at reference wavelength determined in each of the wavelength bands and the rate of sensitivity varying against wavelength varying match with a sensitivity value at reference wavelength of three color matching functions of an XYZ color system and the rate of sensitivity varying against wavelength varying.

A projector of the sixth invention according to the present invention projects and displays an image with the use of the light source device according to any one of the first to fourth inventions.

### Effect of the Invention

The present invention can provide a light source device, which quantitatively measures a color phase of an output luminous flux so that even if light usage efficiency for each wavelength band in a rear optical system, such as a projector, is not uniform, a desired color balance of output light of the rear optical system can be achieved, and can set and maintain a target color phase by feedback control, and a projector.

### BRIEF DESCRIPTION OF THE DRAWINGS

FIG. 1 is a block diagram showing a light source device of the present invention in a simplified manner

FIG. 2 is a block diagram showing the light source device of the present invention in a simplified manner.

FIG. 3 is a schematic diagram showing a portion of the light source device of the present invention in a simplified manner

FIG. 4A is a schematic view of a concept associated with a technique of the light source device of the present invention.

FIG. 4B is a schematic view of the concept associated with the technique of the light source device of the present invention.

FIG. 5 is a block diagram showing a portion of the light source device of the present invention in a simplified manner

FIG. 6 is a block diagram showing a portion of the light source device of the present invention in a simplified manner

FIG. 7 is a schematic diagram showing one mode of a portion of an embodiment of the light source device of the present invention in a simplified manner

FIG. 8 is a schematic diagram showing one mode of a portion of the embodiment of the light source device of the present invention in a simplified manner

FIG. 9 is a view for explaining one mode of a portion of a kind of conventional projector according to a projector of the present invention.

FIG. 10 is a view for explaining one mode of a portion of a kind of conventional projector according to the projector of the present invention.

### MODE FOR CARRYING OUT THE INVENTION

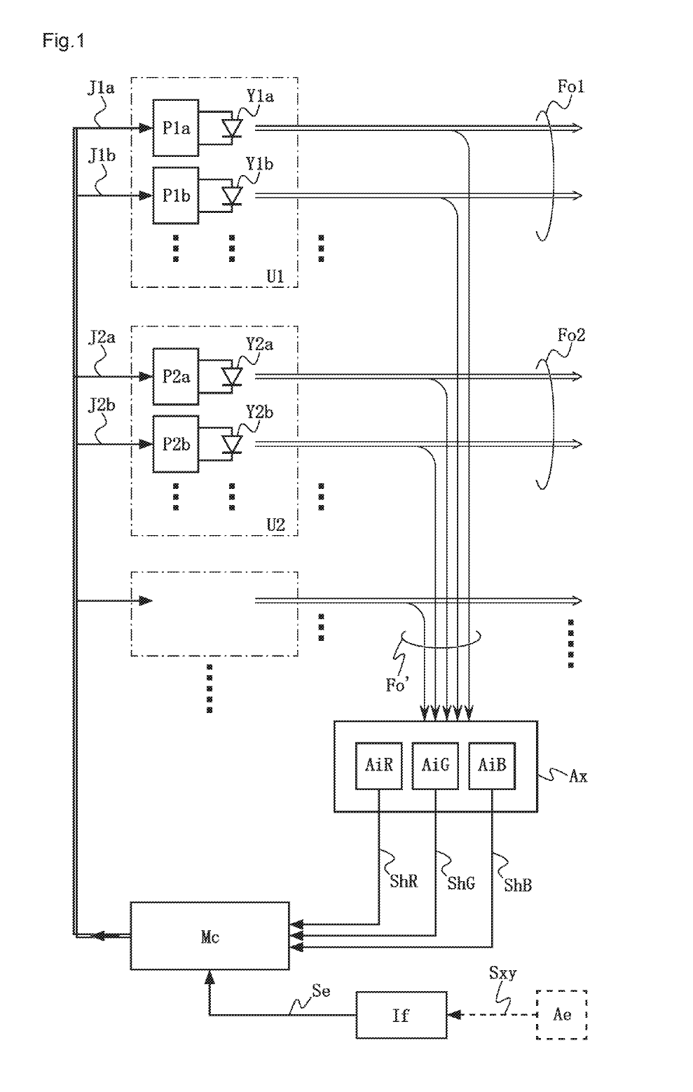

First, an embodiment for practicing the present invention will be described using FIG. 1, which is a block diagram showing a light source device of the present invention in a simplified manner.

At least one light emitting element (Y1a, Y1b, . . . ) provided with the element light source (U1) is driven by a drive circuit (P1a, P1b, . . . ) to emit light.

Regarding the individual light emitting elements (Y1a, Y2b, . . . ), in this case, the light emitting element is, for example, a semiconductor laser or a light source, which converts wavelength of light emitted from a semiconductor laser with the use of non-linear optical phenomenon such as harmonic generation and optical parametric effect. Such light sources are connected in series, in parallel, or in seriesparallel, so that the light emitting element can be driven by the single drive circuit (P1a, P1b, . . . ).

Regarding the drive circuit (P1a, P1b, . . . ), in this case, the drive circuit is a DC/DC converter constituted of, for example, a circuit of a step-down chopper or a step-up chopper type to which power is supplied by a DC power supply (illustration thereof is omitted), and predetermined power can be supplied to the light emitting element (Y1a, Y1b, . . . ).

An integrating control circuit (Mc) is configured to transmit and receive individual data for each of the drive circuits (P1a, P1b, P2a, P2b, . . . ) through a drive circuit control signal (Ea, J1b, J2a, J2b, . . . ) to control the drive circuits, so that predetermined power can be supplied to the light emitting element (Y1a, Y1b, Y2a, Y2b, . . . ).

The light source device of the present invention has a plurality of elemental light sources (U2, . . . ) similar to the elemental light source (U1), and the light emitting elements (Y1a, Y1b, Y2a, Y2b, . . . ) included in the elemental light sources include light emitting elements whose emission wavelength belongs to a plurality of types of different narrow wavelength bands, and the included wavelength bands are three primary colors of R, G, and B in this case.

Accordingly, in order to measure overall light characteristics of output luminous fluxes (Fo1, Fo2, . . . ) of the elemental light sources (U1, U2, . . . ), an output luminous flux for measurement (Fo′) obtained by gathering luminous fluxes extracted partially from the output luminous fluxes (Fo1, Fo2, . . . ) and formed of light whose quantity is correlated with the light quantity of the output luminous fluxes (Fo1, Fo2, . . . ) is generated, and the output luminous flux for measurement (Fo′) is made enter band light characteristics acquisition means (AiR, AiG, AiB) provided for each of the above-described wavelength bands.

Here, when a state in which all the output luminous fluxes (Fo1, Fo2, . . . ) are mixed is assumed, the overall light characteristics indicate the characteristics of the light content and the hue of light for each wavelength band in the entire output luminous flux (Fo1, Fo2, . . . ) with respect to the entire output luminous flux (Fo1, Fo2, . . . ). Even if the output luminous flux (Fo1, Fo2, . . . ) is output by mixing light in the R, G, and B wavelength bands, or even if output luminous fluxes (Fo1, Fo2, . . . ) are separately output, the light in the R, G, and B wavelength bands are mixed finally, and therefore, the state in which all the output luminous fluxes (Fo1, Fo2, . . . ) are mixed is assumed. For example, when the light source device of the present invention is applied to a projector, image information is added to the light in the R, G, and B wavelength bands for each wavelength band by two-dimensional optical amplitude modulation, and then, the light in the R, G, and B wavelength bands are mixed finally.

The correlation with the light quantity of the output luminous flux indicates that the light quantity and the hue for each wavelength band of the output luminous flux (Fo1, Fo2, . . . ) can be estimated by measuring the output luminous flux for measurement (Fo′). In this case, magnification of the correlation (a coefficient of correlation) may be different for each wavelength band since it can be corrected by previous measurement.

The band light characteristics acquisition means (AiR, AiG, AiB) generates band light characteristics acquisition data (ShR, ShG, ShB) for obtaining a light emission intensity instruction value correlated with light intensity and a wavelength deviation instruction value correlated with a deviation from reference wavelength. In the light source device of the present invention, band light characteristics acquisition means having any configuration may be used as long as it can measure/obtain those quantities.

Here, it is described that the output luminous flux for measurement (Fo′) is obtained by gathering luminous fluxes extracted partially from the output luminous fluxes (Fo1, Fo2, . . . ) in the respective wavelength bands, and a band light characteristics acquisition means set (Δx) is obtained by gathering the band light characteristics acquisition means. This description is merely for convenience's sake, and the output luminous fluxes for measurement in the respective wavelength bands may be individually input to the respective band light characteristics acquisition means (AiR, AiG, AiB).

The integrating control circuit (Mc) reads out the band light characteristics acquisition data (ShR, ShG, ShB) including information for obtaining the light emission intensity instruction value and the wavelength deviation instruction value from the band light characteristics acquisition means (AiR, AiG, AiB).

Incidentally, in the case of the above-described projector, for example, the output luminous flux (Fo1, Fo2, . . . ) illuminates two-dimensional optical amplitude modulation elements provided separately for each of R, G, and B colors and provided independently from each color. When a dichroic mirror or a dichroic prism is disposed, the output luminous flux (Fo1, Fo2, . . . ) can be used such that modulated luminous fluxes of three primary colors of R, G, and B are color-synthesized. Alternatively, for example, white light is formed by mixing all the output luminous fluxes (Fo1, Fo2, . . . ), and the white light may be used as a substitute for light from a light source (SjA) constituted of the above-described high intensity discharge lamp and so on.

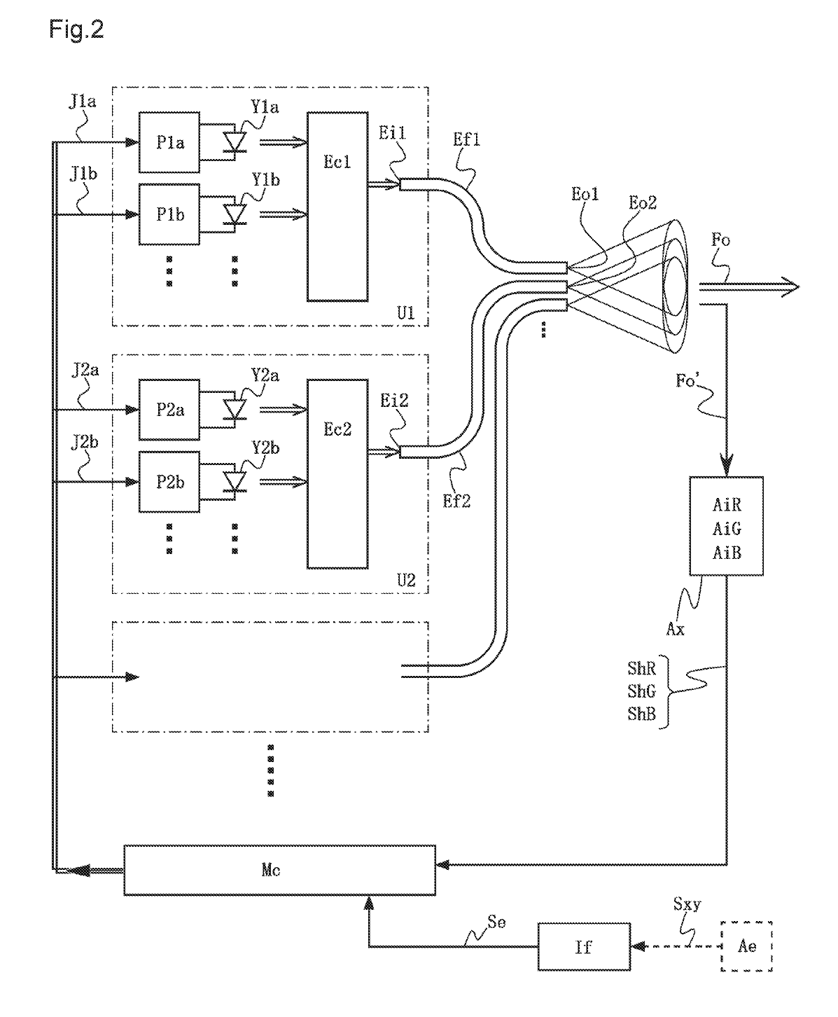

As shown in FIG. 2, which is a block diagram showing the light source device of the present invention in a simplified manner, light emitted from the light emitting elements (Y1a, Y1b, Y2a, Y2b, . . . ) are focused at incident ends (Ei1, Ei2, . . . ) of optical fibers (Ef1, Ef2, . . . ) by focusing optical systems (Ec1, Ec2, . . . ) formed of, for example, a lens, and focused light propagates through cores of the optical fibers (Ef1, Ef2, . . . ) and can be emitted from exit ends (Eo1, Eo2, . . . ).

The light emitted from the exit ends (Eo1, Eo2, . . . ) of the optical fibers (Ef1, Ef2, . . . ) of the elemental light sources (U1, U2, . . . ) are integrated, and the integrated light as a single output luminous flux (Fo) is output from the light source device of the present invention.

As the simplest method of integrating light emitted from a plurality of the exit ends (Eo1, Eo2, . . . ), the exit ends (Eo1, Eo2, . . . ) are aligned so as to be positioned on the same plane, and exit end portions of the optical fibers (Ef1, Ef2, . . . ) are bundled.

The output luminous flux for measurement (Fo′) obtained by partially extracting light emitted from the exit ends (Eo1, Eo2, . . . ) and integrating the light is generated so that a quantity correlated with the light quantity of the output luminous flux (Fo) guided by each of the optical fibers (Ef1, Ef2, . . . ) can be measured, and similarly to the output luminous flux for measurement (Fo′) of FIG. 1, the output luminous flux for measurement (Fo′) can be input to the band light characteristics acquisition means set (Δx) obtained by gathering the band light characteristics acquisition means (AiR, AiG, AiB).

In this configuration, although all exit ends of the optical fibers (Ef1, Ef2, . . . ) are bundled to generate the output luminous flux (Fo) of white light, the exit ends (Eo1, Eo2, . . . ) may be separately bundled for each of the R, G, and B wavelength bands to generate the output luminous flux for each wavelength band and, thus, to be individually input to the band light characteristics acquisition means (AiR, AiG, AiB).

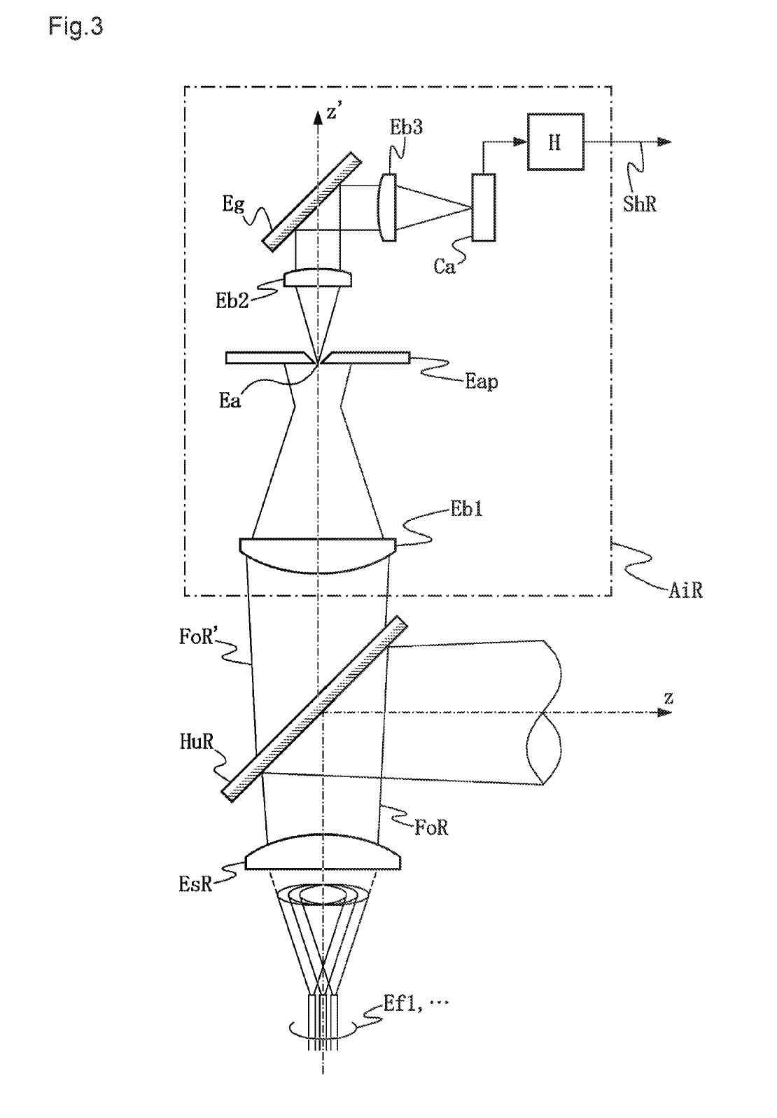

An example in which the band light characteristics acquisition means (AiR, AiG, AiB) is configured is shown in FIG. 3, which is a schematic diagram showing a portion of the light source device of the present invention in a simplified manner.

In this drawing, although the band light characteristics acquisition means is illustrated as the band light characteristics acquisition means (AiR) which generates the band light characteristics acquisition data (ShR) for obtaining the light emission intensity instruction value correlated with the light intensity relating to the R wavelength band and the wavelength deviation instruction value correlated with a deviation from reference wavelength, the same applies to the band light characteristics acquisition means in the wavelength bands in other colors.

The band light characteristics acquisition means (AiR) is configured to generate the band light characteristics acquisition data (ShR) by comprising a wavelength dispersibility optical element (Eg), which changes the traveling direction according to the wavelength of light contained in the received output luminous flux for measurement (Fo′), and an imaging element (Ca) which detects a distribution pattern formed at the back of light whose traveling direction has been changed by the wavelength dispersibility optical element (Eg).

The light emitted from the exit end of the optical fiber (Ef1, . . . ) is converted into the output luminous flux (FoR) of R color of an infinite image through a collimator lens (EsR) to be reflected by a mirror (HuR) and, thus, to be guided in a z-axial direction.

Meanwhile, in a z′ -axial direction, since slightly-existing transmitted light (FoR') leaks from the mirror (HuR), this light is collected into a pinhole (Ea) of an aperture plate (Eap) by a condenser lens (Eb1), and the passing light is taken out backward.

In the taken luminous flux, after an image of the pinhole (Ea) is converted into a luminous flux forming an infinite image by a collimator lens (Eb2), this luminous flux is used as the output luminous flux for measurement and reflected by the wavelength dispersibility optical element (Eg) having a function of changing the traveling direction according to the wavelength of light contained in the output luminous flux for measurement and using a diffraction grating and so on. After that, the luminous flux passes through an image forming lens (Eb3), whereby a spectrally resolved image of the pinhole (Ea) is produced on an output image surface of the image forming lens (Eb3).

Then, an imaging surface of the imaging element (Ca) using a one-dimensional image sensor, for example, is disposed at the position of this image, whereby this image can be imaged.

At this time, it is configured such that a direction in which pixels of the imaging element (Ca) are arranged coincides with a direction in which emitted light is projected such that an angle of the emitted light changes depending on variation of wavelength of light entering the wavelength dispersibility optical element (Eg).

According to the above configuration, a signal processing circuit (H) reads out a distribution pattern of brightness in the spectrally resolved pinhole image obtained by the imaging element (Ca), to calculate the sum of brightness of respective pixels and, thus, to obtain distribution pattern intensity. Moreover, a centroid position of the pattern is calculated to obtain an amount of deviation from a pixel position corresponding to reference wavelength, and the band light characteristics acquisition data (ShR) including the distribution pattern intensity and the deviation amount can be generated.

The position in the z′-axial direction of the pinhole (Ea) is required to be set at a position where all light emitted from the optical fiber (Ef1, . . . ) are superimposed so that the signal processing circuit (H) can obtain the distribution pattern intensity and the deviation amount in which all the light emitted from the optical fiber (Ef1, . . . ) according to the relevant wavelength band are integrated.

Thus, since a central axis of an angular distribution of emitted light from each point of a core at the exit end of each of the optical fibers (Ef1, . . . ), that is, a main light beam is parallel to a central axis of the core of the optical fibers (Ef1, . . . ), that is, the z′ axis, the entrance pupil of the condenser lens (Eb1) is considered to be located at infinity, and it is preferable that the pinhole (Ea) is provided at the center of the exit pupil of the condenser lens (Eb1).

In the integrating control circuit (Mc), the band light characteristics acquisition data (ShR, ShG, ShB) is input from the band light characteristics acquisition means (AiR, AiG, AiB), whereby the distribution pattern intensity and the deviation amount as described above can be obtained for each of the R, G, and B wavelength bands.

Accordingly, the integrating control circuit (Mc) can calculate light emission intensity instruction values Sr, Sg, and Sb, correlated with the light intensity, from the distribution pattern intensity for each of the R, G, and B wavelength bands and further can calculate wavelength deviation instruction values Δλr, Δλg, and Δλb, correlated with the deviation from the reference wavelength, from the amount of deviation from the centroid position of the distribution pattern from the pixel position corresponding to the reference wavelength.

In general, color of light emitted from a light source or the like is represented by chromaticity coordinates based on an XYZ color system established by CIE (reference: “Properties of Colors and Technology”, edited by The Japan Society of Applied Physics/Kogaku Konwakai, published by Asakura Shoten, the first edition was published on Oct. 10, 1986, first printing).

Tristimulus values X, Y, and Z of a luminous flux to be measured, represented by a spectrum S(λ) with the use of a wavelength λ as a parameter are obtained by the following integration calculation (expression 1) with the use of color matching functions xe(λ), ye(λ), and ze(λ) determined by CIE.

Incidentally, integration is performed in a region of from 380 nm to 780 nm

X=∫S(λ)·xe(λ)·dλ (Expression 1)

Y=∫S(λ)·ye(λ)·dλ

Z=∫S(λ)·ze(λ)·dλ

The chromaticity coordinates x, y of the luminous flux to be measured S(λ) are obtained as the following expressions (expression 2) with the use of the above expressions.

x=X/[X+Y+Z] (Expression 20

y=Y/[X+Y+Z]

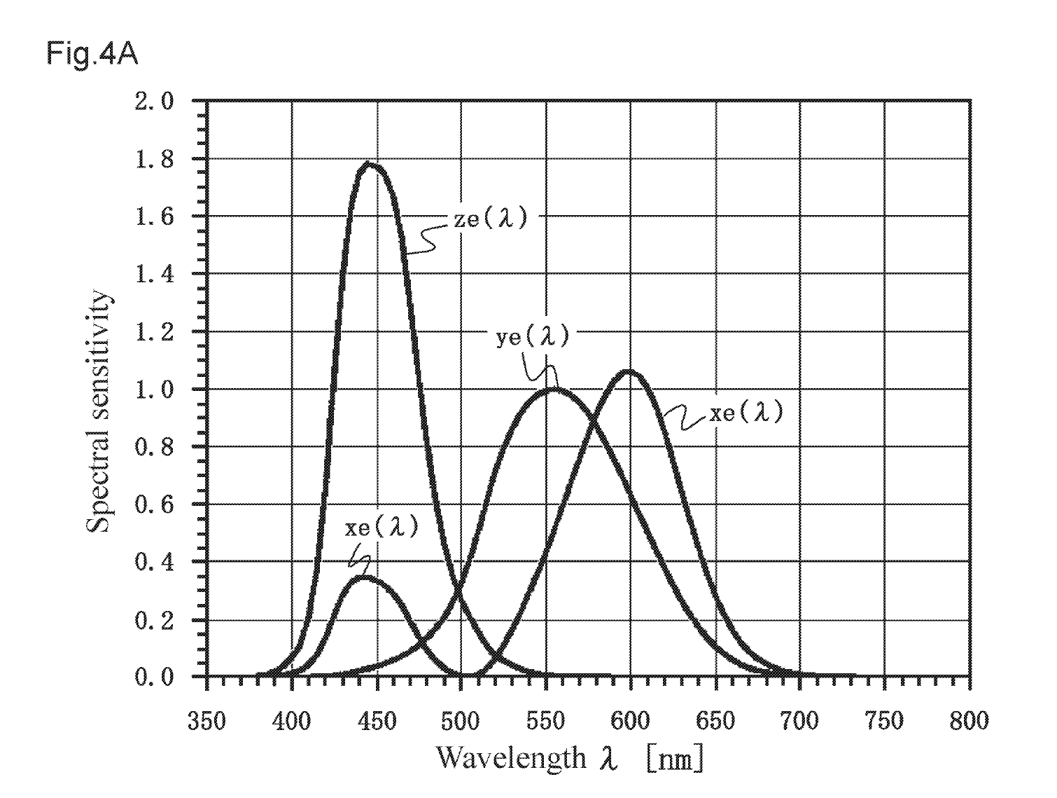

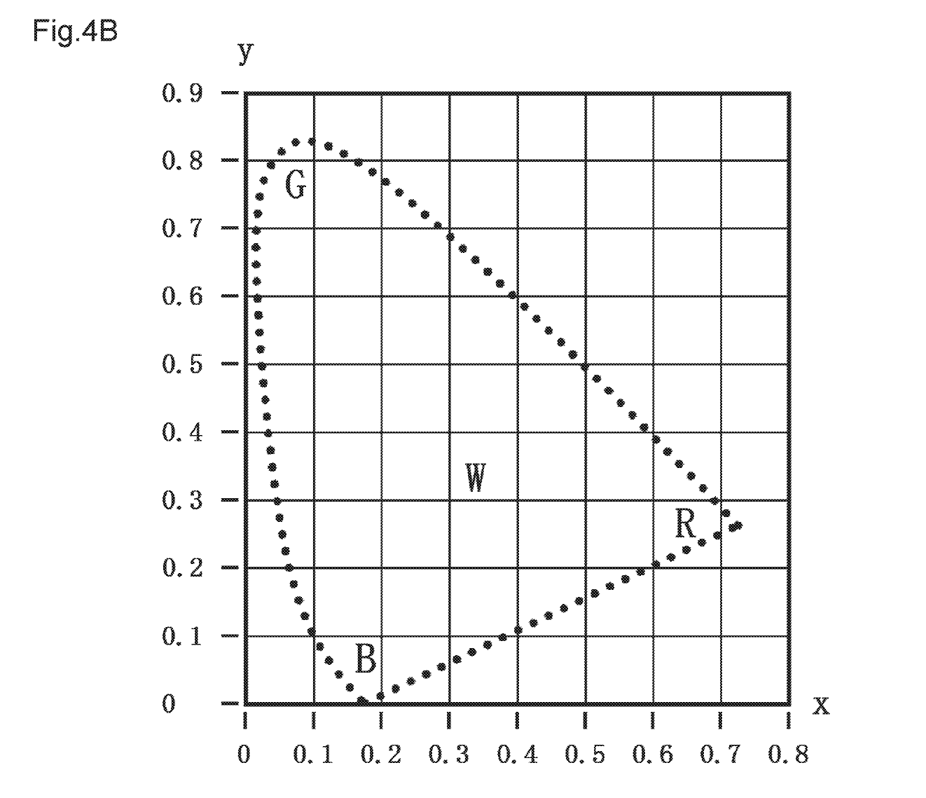

Note that the characteristics of the color matching functions xe(λ), ye(λ), and ze(λ) are as shown in FIG. 4A, which is a schematic view of a concept associated with a technique of the light source device of the present invention. Incidentally, in general documents, as a symbol representing the color matching function, although a symbol to which a crossbar is given above each of characters x, y, and z is used, in this specification the above symbols are used for certain reasons.

The integrating control circuit (Mc) holds, for each of the R, G, and B wavelength bands, local band color matching function information, including a function value in reference wavelength and the rate of function varying against wavelength varying, with respect to the color matching functions xe( ),), ye( ),), and ze(4

Accordingly, as described below, the integrating control circuit (Mc) can approximately calculate the tristimulus values X, Y, and Z or the chromaticity coordinates x, y as the color phase instruction values with the use of the local band color matching function information, based on the light emission intensity instruction values and the wavelength deviation instruction values that are calculated for each of the R, G, and B wavelength bands.

FIG. 4B is a schematic view showing a so-called chromaticity diagram representing a relationship between chromaticity coordinates and colors. All of colors representable in the color system are located on or inside a dashed line in FIG. 4B. In FIG. 4B, schematic positions of red (R), green (G), blue (B), and white (W) are described.

Note that single-color light such as a laser beam is located on the dashed line in the figure (except for a straight line portion from R to B, that is, so-called pure purples).

The chromaticity coordinates of pure white are ⅓ and ⅓.

In FIG. 4B, when the position of white is viewed as a reference, R, G, and B are substantially located on right side, upper side, and lower side, respectively. Therefore, in the chromaticity coordinates of the white light, the value x increases with the increase of R component, the value y increases with the increase of G component, and the value y decreases with the increase of B component.

In order to use the properties of the chromaticity diagram, the integrating control circuit (Mc) obtains light emission intensity instruction values Sr, Sg, and Sb correlated with the light intensity and the wavelength deviation instruction values Δλr, Δλg, and Δλb correlated with the deviation from the reference wavelength to calculate the chromaticity coordinates, and compares the values x and y of the calculated chromaticity coordinates with the respective target values.

For example, if the value x is more than the target value, the integrating control circuit (Mc) decreases the total output power of the drive circuits driving the light emitting elements in the R wavelength band, among the drive circuits (P1a, P1b, P2a, P2b, . . . ), by p % and increases each of the total output power of the drive circuits driving the light emitting elements in the G wavelength band and the total output power of the drive circuits driving the light emitting elements in the B wavelength band by [p/21%. Meanwhile, if the value y is more than the target value, the integrating control circuit (Mc) decreases the total output power of the driving circuits driving the light emitting elements in the G wavelength band by q % and increases the total output power of the driving circuits driving the light emitting elements in the B wavelength band by q %, through the drive circuit control signals (J1a, J1b, J2a, J2b, . . . ).

Then, after appropriate length of time is elapsed, the sequence is returned to a step of obtaining the above-described light quantity measurement data again, whereby the feedback control loop is established.

By virtue of the feedback control loop, the control is constantly performed such that the difference between the chromaticity coordinates and the target values thereof is small with less variation of light intensity. This makes it possible to stabilize the color of light.

Incidentally, if the value x or the value y is less than the target value, the operation of increase and the operation of decrease as described above are reversed.

In addition, the value p and the value q should be small values not causing drastic variation of the color of light. Moreover, the value p and the value q should be small values not causing a phenomenon in which, with respect to the difference between the chromaticity coordinates and the target values thereof before a change in output power due to the decrease or increase by p % or [p/2]% and the decrease or increase by q %, a symbol of the difference between the chromaticity coordinates and the target values thereof after the change in output power is reversed, and the absolute value increases. However, the relationship between the magnitude of the value p with respect to the difference between the value x and the target value thereof and the magnitude of the value q with respect to the difference of the value y and the target value thereof may be preferably determined experimentally.

Note that the increase and decrease of the output power based on the value p and the increase and decrease of the output power based on the value q may be alternately performed. Alternatively, after the values p and q are determined, the increase and decrease of the output power reflecting the both values p and q may be performed.

When the difference between the chromaticity coordinates x, y and the target values thereof is detected, the method of increasing and decreasing the total output power of the drive circuits driving the light emitting elements in each of the R, G, and B wavelength bands based on the values q and p, is not necessarily a method of approaching the target values through the shortest route. However, since the state of the system may be gradually changed toward the target values by the feedback control, the above-described method is sufficiently practical.

Note that the method of approaching the target values through the shortest route will be described later.

Incidentally, the chromaticity coordinates corresponding to pure white is not necessarily favorable as the target chromaticity coordinates. This is because, for example, when the light source device of the present invention is applied to a projector, usage efficiency of light of an optical system of a main body of the projector is not necessarily the same in colors R, G, and B.

For example, if the usage efficiency of B color is low in the optical system of a main body of a certain projector, the target chromaticity coordinates may become bluish chromaticity coordinates including extra B-color component.

Accordingly, the target chromaticity coordinates may be determined not based on the color of the output luminous fluxes (Fo, F1, Fo2, . . . ) of the light source device of the present invention but on the output of an apparatus that uses the light source device of the present invention.

Here, a specific method of determining the target chromaticity coordinates as described herein, that is, a target value of the color phase instruction value will be described later.

In this case, property in which the total output power of the drive circuits driving the light emitting elements in one wavelength band and the light intensity of the component of the one wavelength band are substantially proportionally correlated with each other is used (in the specification, the property is called electric power and light quantity proportion rule). More specifically, there is used property in which, among the drive circuits (P1a, P1b, P2a, P2b, . . . , the total output power Pr of the drive circuits driving the light emitting elements in the R wavelength band, the total output power Pg of the drive circuits driving the light emitting elements in the G wavelength band, and the total output power Pb of the drive circuits driving the light emitting elements of the B wavelength band are substantially proportionally correlated with the light intensity of the component of the respective R, G, and B wavelength bands. As the premise thereof, it is assumed that the light emitting elements emitting the same color light have the same emission efficiency (more pragmatically, the same kind of products by the same manufacturer) although the emission efficiency may be different between the light emitting elements emitting different color light.

Accordingly, in the case where the above-described premise is not applied due to the fact that a plurality of light emitting elements different in emission efficiency are mixed although the light emitting elements emit the same color light, for example, the configuration is devised such that when receiving power setting instruction from the integrating control circuit (Mc) through the drive circuit control signals (J1a, J1b, . . . , J2a, J2b, . . . ), the drive circuits driving the light emitting elements of a kind that are lower in emission efficiency internally set the power larger than the instructed setting power to easily address the case. For example, in the case where in the light emitting elements emitting light in certain color, there are light emitting elements of a kind A that are high in emission efficiency and light emitting elements of a kind B that are lower in emission efficiency by 10% than the light emitting elements of the kind A, the drive circuits driving the light emitting elements of the kind B may internally set the power larger by 10% than the instructed setting power.

Note that, even in the case where proportional accuracy in the above-described electric power and light quantity proportion rule, that is, linearity is not really good, it does not a matter.

This is because it is possible to gradually change the state of the system toward the target values through the feedback control by gradually varying the power as long as the increase of the power and the increase of the light quantity are correlated with each other even if the linear relationship therebetween is not established.

Further, if there are a plurality of target drive circuits when the total output power of the drive circuits driving the light emitting elements in the one wavelength band is changed, all of the drive circuits may be changed at the same rate or different rates, or only specified drive circuits may be changed. Although such various forms are considered, any form may be used.

The power setting to the drive circuit is limited in level. For example, when the setting data length is 8 bits, the grayscale is 256.

Therefore, when the power is increased by minimum unit, the power setting of all of the drive circuits are not increased by 1LSB at a time. The power setting of the drive circuits are separately increased in such a manner that, for example, the power setting of a first drive circuit is increased by 1LSB, and then the power setting of a second drive circuit is increased by 1LSB. When the power setting of a final drive circuit is increased by 1LSB, the power setting of the first drive circuit is increased again by 1LSB, and the increase is continued. As a result, it is advantageously possible to increase the number of grayscale of the power setting to multiple of the number of the drive circuits.

The XYZ color system established by CIE is configured such that the value Y in the above-described expression (expression 1) represents the brightness of the integrated light of all of the included wavelength bands.

Accordingly, the integrating control circuit (Mc) generates a brightness instruction value correlated with brightness of integral light of the output luminous flux (Fo, Fo1, Fo2, . . . ) in addition to a color phase instruction value correlated with color of integrated light of the output luminous flux (Fo, Fo1, Fo2, . . . ) and determines variation of the light emission intensity instruction values for the respective wavelength bands to perform the feedback control of the drive circuit (P1a, P1b, P2a, P2b, . . . ) to reduce a difference between the brightness instruction value and the target value thereof in addition to a difference between the color phase instruction value and the target value thereof. This configuration is preferred.

Namely, when the brightness of the light integrated of all of the R, G, and B wavelength bands is also stabilized in addition to the color phase instruction values correlated with the color of light, the integrating control circuit (Mc) controls the total output power in the respective R, G, and B wavelength bands through the drive circuit control signals (Ea, J1b, J2a, J2b, . . . ) such that the difference between the calculated value Y as the brightness instruction value and the target value of the brightness instruction value is reduced. Namely, the integrating control circuit (Mc) compares the calculated value Y as the brightness instruction value with the target value, and when the value Y is more than the target value, according to the electric power and light quantity proportion rule, the integrating control circuit (Mc) performs control through the drive circuit control signals (J la, J1b, J2a, J2b, . . . ) so as to decrease, among the drive circuits (P1a, P1b, P2a, P2b, . . . ), each of the total output power Pr of the driving circuits driving the light emitting elements in the R wavelength band, the total output power Pg of the drive circuits driving the light emitting elements in the G wavelength band, and the total output power Pb of the drive circuits driving the light emitting elements in the B wavelength band, by Q %. As a result, it is possible to stabilize the brightness of light without varying the color of light by performing the feedback control in a direction in which the difference between the brightness of light and the target value thereof is reduced.

Incidentally, if the value Y is less than the target value, the operation of increase and the operation of decrease described above are reversed.

Further, the value Q should be a small value not causing drastic variation of the brightness of light. Moreover, the value Q should be small values not causing a phenomenon in which, with respect to the difference between the brightness of light and the target values thereof before variation of output power due to the decrease or increase by Q %, a symbol of the difference between the brightness of light and the target values thereof after the variation of output power is reversed, and the absolute value increases. However, the relationship of the magnitude of the value Q with respect to the magnitude of the difference between the value Y and the target value thereof may be preferably determined experimentally.

Note that the increase and decrease of the output power to stabilize the brightness of light described here and the increase and decrease of the output power to stabilize the color of light may be alternately performed. Alternatively, after the values p, q, and Q are each determined, the increase and decrease of the output power reflecting the three values may be performed.

In the detection of the difference between the chromaticity coordinates x and y and the brightness Y and the respective target values, the method of increasing and decreasing the total output power of the drive circuits driving the light emitting elements in each of the R, G, and B wavelength bands based on the values p, q, and Q is not necessarily a method of approaching the target values through the shortest route. However, since the state of the system may be gradually changed toward the target values by the feedback control, the above-described method is also sufficiently practical.

Incidentally, the method of approaching the target values through the shortest route will be described later.

Regarding the way of performing the feedback control for stabilization of the color of light and the brightness of light described above, there has not been shown guideline to quantitatively determine variation of the output power of the drive circuits corresponding to each of the R, G, and B wavelength bands in order to cause the values x, y, and Y to integrally direct toward the respective target values through the shortest route. Therefore, the number of steps of the feedback control asymptotically approaching the target value cannot be reduced.

Here, the guideline to achieve feedback control improved in this point is described.

Namely, the integrating control circuit (Mc) has a guideline to be configured as follows. Namely, the integrating control circuit (Mc) determines a coefficient of a linear operation with the use of the variation of the light emission intensity instruction values. The linear operation represents, with the use of the variation of the light emission intensity instruction values, the variation of the color phase instruction value obtained when the light emission intensity instruction values in the respective wavelength bands are slightly varied. The integrating control circuit (Mc) determines the variation of the light emission intensity instruction value in each of the wavelength bands to perform the feedback control.

As described above, the integrating control circuit (Mc) measures the light emission intensity instruction value correlated with the light intensity based on the band light characteristics acquisition data (ShR, ShG, ShB) from the band light characteristics acquisition means (AiR, AiG, AiB).

Here, the light intensity correlates with optical power of all of the light emitting elements included in one of the wavelength bands, among the light emitting elements (Y1a, Y1b, . . . , Y2a, Y2b, . . . ), and has no relation to human visibility.

On the other hand, since the brightness of light is brightness sensed by a human, the magnitude of the brightness of light varies due to influence of visibility of a human when a wavelength varies even in the case of the same optical power (density).

The integrating control circuit (Mc) determines a coefficient of a linear operation with the use of the light emission intensity instruction values and the wavelength deviation instruction values of the respective R, G, and B wavelength bands. The linear operation represents, with the use of the variation of the light emission intensity instruction values, the variation occurred in the tristimulus values or the chromaticity coordinates as the color phase instruction values when the light emission intensity instruction values of the respective R, G, and B wavelength bands are slightly varied.

Then, with the use of the determined coefficient, the integrating control circuit (Mc) determines variation for slightly varying the light emission intensity instruction values of the respective R, G, and B wavelength bands. Based on the variation, the integrating control circuit (Mc) sets output power of the drive circuits (P1a, P1b, P2a, P2b, . . . ) through the drive circuit control signals (J1a, J1b, J2a, J2b, . . . ), whereby the integrating control circuit (Mc) can perform the feedback control such that the tristimulus values X, Y, Z or the chromaticity coordinates x and y, and the brightness of light Y are maintained at the respective target values.

According to the electric power and light quantity proportion rule, it is considerable that the light emission intensity instruction values of the respective R, G, and B wavelength bands are respectively proportional to the total output power Pr of the drive circuits driving the light emitting elements in the R wavelength band, the total output power Pg of the drive circuits driving the light emitting elements in the G wavelength band, and the total output power Pb of the drive circuits driving the light emitting elements in the B wavelength band, independently, among the drive circuits (P1a, P1b, P2a, P2b, . . . ).

For example, in the case where the light emission intensity instruction values of the respective R, G, and B wavelength bands are all increased by 1%, when the total output power are 200 W, 300 W, and 100 W, respectively, the light emission intensity instruction values are increased to 202 W, 303 W, and 101 W, respectively.

Among the drive circuits (P1a, P1b, P2a, P2b, . . . ) described for the electric power and light quantity proportion rule, the total output power Pr of the drive circuits driving the light emitting elements in the R wavelength band, the total output power Pg of the drive circuits driving the light emitting elements in the G wavelength band, and the total output power Pb of the drive circuits driving the light emitting elements in the B wavelength band may be represented by the following expressions (expression 3). The expressions are represented by independent proportionality coefficients kr, kg, and kb and the target values Srp, Sgp, and Sbp of the light emission intensity instruction values Sr, Sg, and Sb of the respective R, G, and B wavelength bands.

Pr=Kr·Srp (Expression 3)

Pg=Kg·Sgp

Pb=Kb·Sbp

The proportionality coefficients kr, kg, and kb of the above-described (expression 3) can be determined from the ratio of the light emission intensity instruction values Sr, Sg, and Sb, calculated based on the band light characteristics acquisition data (ShR, ShG, ShB) obtained by the band light characteristics acquisition means (AiR, AiG, AiB), and the above-described total output power Pr, Pg, and Pb.

First, it is assumed that safe initial values that are unspecified but appropriately determined are set to the proportionality coefficients kr, kg, and kb, and the total output power Pr, Pg, and Pb that may cause safe initial target values Srp, Sgp, Sbp that are appropriately determined with respect to the light emission intensity instruction values Sr, Sg, and Sb are tentatively determined by the (expression 3) based on the unspecified proportionality coefficients kr, kg, and kb.

The proportionality coefficients kr, kg, and kb may be corrected according to the following expressions (expression 4) with the use of the ratio of the light emission intensity instruction values Sr, Sg, and Sb, obtained from the band light characteristics acquisition means (AiR, AiG, AiB) when the light emitting elements are actually driven with the values of the total output power Pr, Pg, and Pb, and the original target values Srp, Sgp, and Sbp. The equal sign in each expression of the expression 4 indicates that calculation result on right side is assigned to the variable on left side, which is represented according to notation of calculation instruction of typical programming language such as C.

kr=kr·Srp/Sr (Expression 4)

kg=kg·Sgp/Sg

kb=kb·Sbp/Sb

This correction may be performed every measurement performed by the band light characteristics acquisition means (AiR, AiG, AiB) while determining the slight variation ΔSr, ΔSg, and ΔSb of the light emission intensity instruction values Sr, Sg, and Sb, updating the target values Srp, Sgp, and Sbp according to the following expressions (expression 5), and resetting power according to the above-described (expression 3), in repeat of the feedback control loop as described later.

Srp=Sr+ΔSr (Expression 5)

Sgp=Sg+ΔSg

Sbp=Sb+ΔSb

As a result, as described above, even if the proportionality coefficients kr, kg, and kb are not true proportionality constants but are non-linear coefficients showing saturation tendency, correction is repeatedly performed as a merely ratio defined by the (expression 3). Thus, a correct correspondence between the total output power Pr, Pg, and Pb of the drive circuits of R, G, and B and the light emission intensity instruction values Sr, Sg, and Sb (and the target values Srp, Sgp, and Sbp) is maintained.

Subsequently, there will be described a method of determining the variation ΔSr, ΔSg, and ΔSb when the light emission intensity instruction values Sr, Sg, and Sb are slightly varied, in order to perform the feedback control such that the tristimulus values X, Y, and Z are maintained to the target values thereof or the chromaticity coordinates x and y and the brightness of light Y are maintained to the target values thereof, with the use of the light emission intensity instruction values Sr, Sg, and Sb and the values of the deviation from reference wavelength Δλr, Δλg, and Δλb as the wavelength deviation instruction values that are specifically determined.

As described above, focusing on the chromaticity coordinates x, y as the color phase instruction values correlated with the color of light and further focusing on the value Y as the brightness instruction value correlated with the brightness of light, stabilization control thereof has been described.

However, the system of x, y, and Y and the system of X, Y, and Z may be converted from each other by the above-described (expression 2) and the following expressions (expression 6). Therefore, the tristimulus values are values correlated with the chromaticity coordinates. Thus, any of the chromaticity coordinates and the tristimulus values may be employed as the color phase instruction values correlated with the color of light.

X=Y·x/y (Expression 6)

Z=Y·(1−x−y)/y

Thus, a case where the tristimulus values X, Y, and Z are control targets and are controlled to be maintained to the target values Xp, Yp, and Zp will be first described.

Typically, variation Af in the function f=f(λ) when the variable λ of the function f is slightly varied by Δλ is approximated by the following expression (expression 7) with the use of the derivative df/d2, of the function f.

Δf=(df/dλ)·Δλ (Expression 7)

The (expression 7) is applied to the above-described color matching functions xe(λ), ye(λ), and ze(λ), the wavelength λ is represented by λ=λro+Δkr in the case where the wavelength λ is in the vicinity of km, and the following expressions (expression 8) is obtained.

xe(λ)=xe9λr₀+Δλr)=xe(λr₀)+Fxr0·Δλr (Expression 8)

ye(λ)=ye(λr₀+Δkr)=ye(λr₀)+Fyr₀·Δλr

ze(λ)=ze(λr₀+Δkr)=ze(λr₀)+Fzr₀·Δkr

where

Fxr₀=dxe/dλ (λ=λr₀)

Fyr₀=dye/dλ (λ=λr₀)

Fzr₀=dze/dλ (λ=λr₀)

Likewise, when the variable λ is represented by λ=λg₀+Δλg in the case where the variable λ is in the vicinity of ago, the following expressions (expression 9) are obtained.

xe(λ)=xe(λg₀+Δλg)=xe(λg₀)+Fxg₀·Δλg (Expression 9)

ye(λ)=ye(λg₀+Δλg)=ye(λg₀)+Fyg₀·Δλg

ze(λ)=ze(λg₀+Δλg)=ze(λg₀)+Fzg₀·Δλg

where

Fxg₀=dxe/dk(λ=λg₀)

Fyg₀=dye/dλ(λ=λg₀)

Fzg₀=dze/dλ(λ=λg₀)

Further, when the variable λ is represented by λ=λb₀+Δλb in the case where the variable λ is in the vicinity of λb₀, the following expressions (expression 10) are obtained.

xe(λ)=xe(λb₀+Δλb)=xe(λb₀)+Fxb₀·Δλb (Expression 10)

ye(λ)=ye(λb₀+Δλb)=ye(λb₀)+Fyb₀·Δλb

ze(λ)=ze(λb₀+Δλb)=ze(λb₀)+Fzb₀·Δλb

where

Fxb₀=dxe/dλ(λ=λb₀)

Fyb₀=dye/dλ(λ=λb₀)

Fzb₀=dze/dλ(λ=λb₀)

Here, when the luminous flux to be measured S(λ) is approximated to be formed of three primary colors R, G, and B, the luminous flux to be measured S(λ) is represented by the following expression (expression 11) with the use of the delta function δ(λ).

$$S ( λ ) = Sr \cdot δ ( λ - λ {r}_{0} - Δλ r ) + Sg \cdot δ ( λ - λ {g}_{0} - Δλ g ) + Sb \cdot δ ( λ - λ {b}_{0} - Δλ b ) \qquad ( Expression 11 )$$

Accordingly, the (expression 11) and the above-described (expression 8), (expression 9), and (expression 10) are applied to integration of the above-described (expression 1) to obtain the following expressions (expression 12) relating to the value X of the tristimulus values, the following expressions (expression 13) relating to the value Y of the tristimulus values, and the following expressions (expression 14) relating to the value Z of the tristimulus values.

$$X = Sr \cdot [ xe ( λ {r}_{0} ) + {Fxr}_{0} \cdot Δλ r ] + Sg \cdot [ xe ( λ {g}_{0} ) + {Fxg}_{0} \cdot Δλ g ] + Sb \cdot [ xe ( {λb}_{0} ) + {Fxb}_{0} \cdot Δλ b ] = + Hxr \cdot Sr + Hxg \cdot Sg + Hxb \cdot Sb \qquad ( Expression 12 )$$

where

Hxr=xe(λr₀)+Fxr₀·Δλr

Hxg=xe(λg₀)+Fxg₀·Δλg

Hxb=xe(λb₀)+Fxb₀·Δλg

$$Y = Sr \cdot [ ye ( λ {r}_{0} ) + {Fyr}_{0} \cdot Δλ r ] + Sg \cdot [ ye ( λ {g}_{0} ) + {Fyg}_{0} \cdot Δλ g ] + Sb \cdot [ ye ( {λb}_{0} ) + {Fyb}_{0} \cdot Δλ b ] = + Hyr \cdot Sr + Hyg \cdot Sg + Hyb \cdot Sb \qquad ( Expression 13 )$$

where,

Hyr=ye(λr₀)+Fyr₀·Δλr

Hyg=ye(λg₀)+Fyg₀·Δλg

Hyb=ye(λb₀)+Fyb₀·Δλb

$$Z = Sr \cdot [ ze ( λ {r}_{0} ) + {Fzr}_{0} \cdot Δλ r ] + Sg \cdot [ ze ( λ {g}_{0} ) + {Fzg}_{0} \cdot Δλ g ] + Sb \cdot [ ze ( {λb}_{0} ) + {Fzb}_{0} \cdot Δλ b ] = + Hzr \cdot Sr + Hzg \cdot Sg + Hzb \cdot Sb \qquad ( Expression 14 )$$

where,

Hzr=ze(λr₀)+Fzr₀·Δλr

Hzg=ze(λg₀)+Fzg₀·Δλg

Hzb=ze(λb₀)+Fzb₀·Δλg

The variation ΔX, ΔY, and ΔZ of the tristimulus values X, Y, and Z when the light emission intensity instruction values Sr, Sg, and Sb are slightly varied can be represented by the following expressions (expression 15) based on the above-described (expression 12), (expression 13), and (expression 14).

ΔX=Hxr·ΔSr+Hxg·ΔSg+Hxb·ΔSb (Expression 15)

ΔY=Hyr·ΔSr+Hyg·ΔSg+Hyb·ΔSb

ΔZ=Hzr·ΔSr+Hzg·ΔSg+Hzb·ΔSb

In this way, the variation of the color phase instruction values when the light emission intensity instruction values for the respective wavelength bands are slightly varied can be represented by the linear operation with the use of the variation of the light emission intensity instruction values, and the coefficients at that time can be determined with the use of the light emission intensity instruction values and the wavelength deviation instruction values for the respective wavelength bands.

In the feedback control, when considering that the slight variation ΔSr, ΔSg, and ΔSb are added to the light emission intensity instruction values Sr, Sg, and Sb in order to allow the current tristimulus values X, Y, and Z to approach the respective target values Xp, Yp, and Zp, the values ΔX, ΔY, and ΔZ are determined by the following expressions (expression 16) where a dumping coefficient D is from 0 to 1. As a result, the above-described (expression 15) is regarded as an elemental simultaneous linear equation with three unknowns relating to the slight variation ΔSr, ΔSg, and ΔSb. Accordingly, since all of the coefficients thereof are determined, the (expression 15) can be easily solved to determine the slight variation ΔSr, ΔSg, and ΔSb of the light emission intensity instruction values.

ΔX=D·[Xp−X] (Expression 16)

ΔY=D·[Yp−Y]

ΔZ=D·[Zp−Z]

The determined slight variation ΔSr, ΔSg, and ΔSb obtained according to the above-described (expression 5) are added to the original light emission intensity instruction values Sr, Sg, and Sb to calculate new target values Srp, Sgp, and Sbp of the light emission intensity instruction values. Then, the total output power Pr, Pg, and Pb of the drive circuits (P1a, P1b, P2a, P2b, . . . ) can be updated through the above-described (expression 3).

The way of the feedback control of the variation of the color phase instruction values through the (expression 15) represented by the linear operation, with the use of the variation of the light emission intensity instruction values is summarized as follows.

First, the values of the coefficients Hxr, Hxg, Hxb, Hyr, Hyg, Hyb, Hzr, Hzg, and Hzb are provided in advance according to the (expression 12), (expression 13), and (expression 14).

The integrating control circuit (Mc) determines appropriate initial target values Srp, Sgp, and Sbp of the light emission intensity instruction values Sr, Sg, and Sb for the respective R, G, and B wavelength bands and further determines appropriate initial values of the proportionality coefficients kr, kg, and kb. The integrating control circuit (Mc) then sets the total output power Pr, Pg, and Pb of the drive circuits (P1a, P1b, P2a, P2b, . . . ) with the use of the (expression 3), starts driving of the light emitting elements (Y1a, Y1b, Y2a, Y2b, . . . ), and waits during a warm-up period appropriately determined.

The light emission intensity instruction values Sr, Sg, and Sb calculated based on the band light characteristics acquisition data (ShR, ShG, ShB) obtained by the band light characteristics acquisition means (AiR, AiG, AiB) and the original target values Srp, Sgp, and Sbp are applied to the (expression 4) to update the proportionality coefficients kr, kg, and kb.

When the tristimulus values X, Y, and Z, calculated through the (expression 12), (expression 13), and (expression 14) based on the obtained light emission intensity instruction values Sr, Sg, and Sb, and the target values Xp, Yp, and Zp thereof are applied to the (expression 16), the left side of the (expression 15) is determined. Thus, the (expression 15) is regarded as the simultaneous linear equation with three unknowns and solved to obtain the slight variation ΔSr, ΔSg, and ΔSb of the light emission intensity instruction values.

The integrating control circuit (Mc) applies, with respect to the current values Sr, Sg, and Sb of the light emission intensity instruction values, the obtained slight variation ΔSr, ΔSg, and ΔSb to the (expression 5) to calculate new target values Srp, Sgp, and Sbp of the light emission intensity instruction values. The integrating control circuit (Mc) then updates the total output power Pr, Pg, and Pb of the drive circuits (PI a, P1b, P2a, P2b, . . . ) according to the (expression 3).

The integrating control circuit (Mc) then returns to the operation of obtaining the band light characteristics acquisition data (ShR, ShG, ShB). Subsequently, the above-described sequence is repeated to build the feedback control loop.

Note that the slight variation ΔSr, ΔSg, and ΔSb are suppressed to be small with the decrease of the above-described dumping coefficient D, which exhibits an effect of decreasing variation rate of the feedback control to prevent unstable phenomenon such as overrun and oscillation.

Incidentally, the dumping coefficient may be preferably determined experimentally to be suitable value since excessively small value may cause inconvenience, for example, excess time is necessary to complete correction.

In the case where one of the light emission intensity instruction values Sr, Sg, and Sb, for example, Sr is determined separately for any reason (for example, in a case of reaching rating), the target values Xp, Yp, and Zp of the tristimulus values are not met. It is necessary to change control system such that the color of light is maintained to a target color while giving up maintaining the brightness of light.

In a case of a method of performing control such that the above-described tristimulus values X, Y, and Z are maintained to the target values Xp, Yp, and Zp, for example, when the brightness of light is reduced such that the light emission intensity instruction value Sr becomes a predetermined value while maintaining the target color of light, the target values Xp, Yp, and Zp of the tristimulus values are tentatively reduced at the same rate appropriately determined, and the feedback loop is actually performed through trial and error until an appropriate rate such that the light emission intensity instruction value Sr becomes the predetermined value is found.

In contrast, when the chromaticity coordinates x, y that is the color phase instruction values correlated with the color of light and the value Y that is the brightness instruction value correlated with the brightness of light are target of control, and if the control system of maintaining the values x, y, and Y to the target values xp, yp, and Yp is achieved, for example, it becomes possible to perform the feedback control to maintain only the chromaticity coordinates x, y to the target values while the value Sr is fixed.

Hereinafter, a case where the control targets are the values x, y, and Y and control is performed such that the values x, y, and Y are maintained to the target values xp, yp, and Yp will be described.

When the above-described (expression 12), (expression 13), and (expression 14) relating to the tristimulus values X, Y, and Z are applied in order to calculate the chromaticity coordinates x, y, the following expressions (expression 17) relating to sum of the tristimulus values X, Y, and Z is obtained.

$$T = X + Y + Z = [ Hxr + Hyr + Hzr ] \cdot Sr + [ Hxg + Hyg + Hzg ] \cdot Sg + [ Hxb + Hyb + Hzb ] \cdot Sb = Ir \cdot Sr + Ig \cdot Sg + Ib \cdot Sb \qquad ( Expression 17 )$$

where

Ir=Hxr+Hyr+Hzr

Ig=Hxg+Hyg+Hzg

Ib=Hxb+Hyb+Hzb

Accordingly, the chromaticity coordinates x, y in the above-described (expression 2) relating to the luminous flux to be measured S(λ) are calculated by the following expressions (expression 18) with the use of the above-described (expression 12), (expression 13), and (expression 17).

x=X/t (Expression 18)

y=Y/T

Typically, variation in the function f=f(u, v, w) when variables u, v, and w of the function f are slightly varied is approximated to the following expression (expression 19) with the use of partial derivatives δf/δu, δf/δv, and δf/δw of the function f.

Δf=(δf/δu)·Δu+(δf/δv)·Δv+(δf/δw)·Δw (Expression 19)

When the chromaticity coordinates x, y and the brightness of light Y are regarded as functions including the light emission intensity instruction values Sr, Sg, and Sb as variables, the values of the partial derivatives are specifically determined as the following expressions (expression 20). Accordingly, the variations Δx, Δy, and ΔY of the chromaticity coordinates x, y and the brightness of light Y when the light emission intensity instruction values Sr, Sg, and Sb are slightly varied can be represented by the following expressions (expression 21).

$$Jxr = \partial x / δ Sr = [ δ X / δ Sr \cdot T - X \cdot δ T / δ Sr ] / [ T \cdot T ] = [ Hxr \cdot T - Ir \cdot X ] / [ T \cdot T ] = [ Hxr - Ir \cdot x ] / T \\ Jxg = δ x / δ Sg = [ Hxg - Ig \cdot x ] / T \\ Jxb = δ x / δ Sb = [ Hxb - Ib \cdot x ] / T \\ Jyr = δ y / δ Sr = [ Hyr - Ir \cdot y ] / T \\ Jyg = δ y / δ Sg = [ Hyg - Ig \cdot y ] / T \\ Jyb = δ y / δ Sb = [ Hyb - Ib \cdot y ] / T \qquad ( Expression 20 )$$

Δx=Jxr·ΔSr+Jxg·ΔSg+Jxb·ΔSb (Expression 21)

Δy=Jyr·ΔSr+Jyg·ΔSg+Jyb·ΔSb

ΔY=Hyr·ΔSr+Hyg·ΔSg+Hyb·ΔSb

In this way, the variation of the color phase instruction values when the light emission intensity instruction values are slightly varied for the respective wavelength bands can be represented by the linear operation with the use of the variation of the light emission intensity instruction values. In addition, the coefficients at that time can be determined with the use of the light emission intensity instruction values and the wavelength deviation instruction values for the respective wavelength bands.

Incidentally, the third expression relating to the variation ΔY in the (expression 21) is based on the following relationship obtained from the (expression 13).

δY/δSr=Hyr

δY/δSg=Hyg

δY/δSb 32 Hyb

As described regarding the above-described (expression 16), it is considered that the light emission intensity instruction values Sr, Sg, and Sb are slightly varied in order to allow the current values x, y, and Y to approach the target values xp, yp, and Yp in the feedback control. When the dumping coefficient D is from 0 to 1, the variation Δx, Δy, and ΔY are determined by the following expressions (expression 22). As a result, the above-described (expression 21) is regarded as an elemental simultaneous linear equation with three unknowns relating to the slight variation ΔSr, ΔSg, and ΔSb of the light emission intensity instruction values. Accordingly, since all of the coefficients are determined, the equation can be easily solved to determine the values of the slight variation ΔSr, ΔSg, and ΔSb of the light emission intensity instruction values.

Δx=D·[xp−x] (Expression 22)

Δy=D·[yp−y]

ΔY=D·[Yp−Y]

The way of the feedback control of the variation of the color phase instruction values through the (expression 21) represented by the linear operation, with the use of the variation of the light emission intensity instruction values is summarized as follows.

The local band color matching function information relating to the color matching functions xe(λ), ye(λ), and ze( ),) is provided in advance. Namely, the values of the function values xe(λro), ye(λro), ze(λro), xe(λro), ye(λro), ze(λgo), xe(λbo), ye(λbo), and ze(kbo) at the reference wavelengths λm, λgo, and λbo of the respective R, G, and B wavelength bands, and the values of the rate of function varying against wavelength varying Fxro, Fyro, Fzro, Fxgo, Fygo, Fzgo, Fxbo, Fybo, and Fzbo are provided in advance.

Regarding the light emission intensity instruction values Sr, Sg, and Sb for the respective R, G, and B wavelength bands, the integrating control circuit (Mc) determines appropriate initial target values Srp, Sgp, and Sbp. The integrating control circuit (Mc) further determines appropriate initial values of the proportionality coefficients kr, kg, and kb. The integrating control circuit (Mc) then sets the total output power Pr, Pg, and Pb of the drive circuits (P1a, P1b, P2a, P2b, . . . ) with the use of the (expression 3), starts driving of the light emitting elements (Y1a, Y1b, Y2a, Y2b, . . . ), and waits during a warm-up period appropriately determined.

The proportionality coefficients kr, kg, and kb are updated by applying the light emission intensity instruction values Sr, Sg, and Sb, calculated based on the band light characteristics acquisition data (ShR, ShG, ShB) obtained by the band light characteristics acquisition means (AiR, AiG, AiB), and the original target values Srp, Sgp, and Sbp to the (expression 4).

Then, the light emission intensity instruction values Sr, Sg, and Sb and the values of the deviation from reference wavelength Δλr, Δλg, and Δλb as the wavelength deviation instruction values are applied to the above-described (expression 12), (expression 13), and (expression 17). As a result, the tristimulus values X and Y and the value T are obtained through auxiliary coefficients Hxr, Hxg, Hxb, Hyr, Hyg, Hyb, Hzr, Hzg, Hzb, Ir, Ig, and lb. Then, the values of the chromaticity coordinates x, y can be obtained by applying the obtained values to the above-described (expression 18).

When the determined values x, y, and Y and the target values xp, yp, and Yp are applied to the above-described (expression 22), the left side of the above-described (expression 21) is determined. In addition, the coefficients on the right side of the (expression 21) are determined by the coefficients Jxr, Jxg, Jxb, Jyr, Jyg, and Jyb in the above-described (expression 20). Therefore, the (expression 21) is regarded as the simultaneous linear equation with three unknowns and is solved to determine the values of the slight variation ΔSr, ΔSg, and ΔSb of the light emission intensity instruction values.

The integrating control circuit (Mc) applies, with respect to the current values Sr, Sg, and Sb of the light emission intensity instruction values, the determined slight variation ΔSr, ΔSg, and ΔSb to the (expression 5) to calculate new target values Srp, Sgp, and Sbp of the light emission intensity instruction values. The integrating control circuit (Mc) then updates the total output power Pr, Pg, and Pb of the drive circuits (P1a, P1b, P2a, P2b, . . . ) according to the (expression 3).

The integrating control circuit (Mc) then returns to the operation of obtaining the band light characteristics acquisition data (ShR, ShG, ShB). Subsequently, the above-described sequence is repeated to build the feedback control loop.

In the case where one of the slight variation ΔSr, ΔSg, and ΔSb of the light emission intensity instruction values Sr, Sg, and Sb, for example, the slight variation ΔSr is determined separately for any reason (for example, in a case of reaching rating), the slight variation ΔSr is regarded not as the unknown value, but as a constant in the (expression 21), and the following expressions (expression 23) that are obtained by modifying the (expression 21) may be applied. The (expression 23) is an elemental simultaneous linear equation with two unknowns, which can be easily solved. Therefore, the slight variation ΔSg and ΔSb can be obtained. In such a case, although the brightness of light Y cannot be maintained to the target value, the feedback control to maintain the chromaticity coordinates x, y to the target values can be performed.

Δx−Jxr·ΔSr=Hxg·ΔSg+Jxb·ΔSb (Expression 23)

Δy−Jyr·ΔSr=Jyg·ΔSg+Jyb·ΔSb

Here, validity of approximation of the luminous flux to be measured S(λ) by the delta function that is described in the (expression 11) is additionally described.

When the plurality of light emitting elements is collected, fluctuation occurs in emission wavelength even if the colors of the light emitting elements are the same. Thus, the spectrum S(λ) of light that is obtained by integrating light emitted from the light emitting elements does not actually become the delta function as the (expression 11).

Even if fluctuation occurs in emission wavelength, however, the above-described discussion is established by integrating all of the light emitting elements included in the same wavelength band to replace the light emitting elements with a virtual single-color light source that has a wavelength equal to an average value of the wavelengths of the integrated light emitting elements.

Incidentally, when all of the light emitting elements included in the same wavelength band are integrated, expansion of the spectrum width caused by the fluctuation of the wavelength exists. As a result, the chromaticity coordinates slightly move toward white.

However, the movement is small, and the calculation of the chromaticity coordinates and the like in this light source device is not to determine accurate absolute values but to correct, through the feedback control, impaired white balance that is caused by variation of the emission wavelength due to temperature increase of the light emitting elements and the like. Since the expansion of the spectrum width caused by the fluctuation of wavelength exists before such variation of the emission wavelength occurs. Accordingly, practical disadvantage does not occur to achieve the object of the calculation.

Further, the target values xp, yp, and Yp of the feedback control are additionally described.

As described above, various kinds of approximation calculation are performed while assuming that the object of the calculation of the chromaticity coordinates and the like in this light source device is not determination of accurate absolute values.

Thus, if the target values xp, yp, and Yp are provided as a numerical values, it is unknown whether the state achieved by the feedback control becomes desirable state. Such usage is not suitable.

For example, in a case where this light source device is applied to a projector, the light source device is actually mounted on an actual unit of the projector, and an image to be white color is projected on a screen. The light intensity of each of R, G, and B of the light source device is adjusted so as to obtain desired white color. The values x, y, and Y measured by the light source device itself at the end of the adjustment are preferably stored as the target values xp, yp, and Yp.

Incidentally, the comparison of the chromaticity coordinates of desired white color and the measured chromaticity coordinates and the adjustment of the light intensity may not be manually performed by a human. A method causing the light source device itself to perform the comparison and the adjustment, i.e., a method of specifically determining the target chromaticity coordinates, that is, the target value of the color phase instruction value will be described later.

Here, the actual values of the stored target values do not matter. The state where the desired white color is obtainable is achieved by performing the feedback control after that.

The above statement relating to the target values xp, yp, and Yp applies to the target values Xp, Yp, and Zp of the tristimulus values.

The determination of the deviation from reference wavelength Δλr, Δλg, and Δλb based on the band light characteristics acquisition data (ShR, ShG, ShB) obtained by the band light characteristics acquisition means (AiR, AiG, AiB) and calculation of the tristimulus values X, Y, and Z and the chromaticity coordinates x, y at that time with the use of the deviation from reference wavelength have been described.

In addition, there has been presented the calculation method using the determined values of the deviation from reference wavelength Δλr, Δλg, amd Δλb in determination of the coefficients Hxr, Hxg, Hxb, Hyr, Hyg, Hyb, Hzr, Hzg, Hzb, Jxr, Jxg, Jxb, Jyr, Jyg, and Jyb of the above-described (expression 15) and (expression 21) that are linear equations for the feedback control.

Regarding these coefficients, however, it is possible to determine the values by approximating all of the deviation from reference wavelength Δλr, Δλg, and Δλb to zero.

The reason is as follows. Namely, although accuracy of the calculation is deteriorated by this approximation, influence of the deterioration appears as slight deviation of the directions of the respective vectors WC, ΔY, and ΔZ and Δx, Δy, and ΔY obtained by solving the above-described (expression 15) and (expression 21), as compared with those in the case where approximation is not performed. Thus, since the calculation is repeatedly performed in the feedback control loop, even if deviation occurs, the tristimulus values X, Y, and Z and the chromaticity coordinates x and y approach asymptotically to the target values Xp, Yp, Zp, xp, and yp, respectively.

When such approximation is performed, although asymptotic speed to the targets may be deteriorated, calculation of the coefficients is simplified advantageously.

Hereinafter, the calculation method in the case where the approximation is performed in such a manner will be described.

When the light emission intensity instruction values under approximation in which the deviation from reference wavelength is approximated to zero are denoted by Sr, Sg, and Sb that are the same symbols in the case where approximation is not performed, the tristimulus values X, Y, and Z corresponding to the above-described(expression 12), (expression 13), and (expression 14) are represented by the following expressions (expression 24).

X=Hxr₀·Sr+Hxg₀·Sg+Hxb₀·Sb (Expression 24)

Y=Hyr₀·Sr+Hyg₀·Sg+Hyb₀·Sb

Z=Hzr₀·Sr+Hzg₀·Sg+Hzb₀·Sb

where

Hxr=xe(λr₀)

Hxg₀=xe(λg₀)

Hxb₀=xe(λb₀)

Hyr₀=ye(λr₀)

Hyg₀=ye(λg₀)

Hyb₀=ye(λb₀)

Hzr₀=ze(λr₀)

Hzg₀=ze(λg₀)

Hzb₀=ze(λb₀)

As a result, the following expressions (expression 25) are obtained as the equations to be solved in the feedback control loop in place of the above-described (expression 15).

ΔX=Hxr₀·ΔSr+Hxg₀·ΔSg+Hxb₀·ΔSb (Expression 25)

ΔY=Hyr₀·ΔSr+Hyg₀·ΔSg+Hyb₀·ΔSb

ΔZ=Hzr₀·ΔSr+Hzg₀·ΔSg+Hzb₀·ΔSb

Thus, the variation of the color phase instruction values obtained when the light emission intensity instruction values for the respective wavelength bands are slightly varied can be represented by the linear operation with the use of the variation of the light emission intensity instruction values, and the coefficients at that time can be determined.

The values ΔX, ΔY, and ΔZ on the left side of the expressions may be calculated with the use of the above-described (expression 16) based on the target values Xp, Yp, and Zp of the tristimulus values and the values of the tristimulus values X, Y, and Z at that time.

The values of the tristimulus values X, Y, and Z may be determined by calculating the above-described (expression 12), (expression 13), and (expression 14) after the light emission intensity instruction values Sr, Sg, and Sb, calculated based on the band light characteristics acquisition data (ShR, ShG, ShB) obtained by the band light characteristics acquisition means (AiR, AiG, AiB), and the deviation from reference wavelength Δλr, Δλg, and Δλb as the wavelength deviation instruction values.

Likewise, Ir, Ig, and lb of the above-described (expression 17) relating to the chromaticity coordinates x, y under the approximation in which the deviation from reference wavelength is approximated to zero and expressions corresponding to the (expression 20) can be represented by the following expressions (expression 26) and (expression 27) when the deviation from reference wavelength Δλr, Δλg, and Δλb are each assumed to be zero.

Ir₀=Hxr₀+Hzr₀ (Expression 26)

Ig₀=Hxg₀+Hyg₀+Hzg₀

Ib₀=Hxb₀+Hyb₀+Hzb₀

Jxr₀=[Hxr₀−Ir₀·x]/T (Expression 27)

Jxg₀=[Hxg₀−Ig₀·x]/T

Jxb₀=[Hxb₀−Ib·x]/T

Jyr₀=[Hyr₀−Ir₀·y]/T

Jyg₀=[Hyg₀−Ig₀·y]/T

Jyb₀=[Hyb₀−Ib₀·y]/T

Incidentally, as described above, the values x, y, and T are calculated by applying the values of the tristimulus values X, Y, and Z that are calculated by the above-described (expression 12), (expression 13), and (expression 14) to the uppermost expression of the above-described (expression 17), namely, the following expression and to the (expression 18) after the light emission intensity instruction values Sr, Sg, and Sb, calculated based on the band light characteristics acquisition data (ShR, ShG, ShB) obtained by the band light characteristics acquisition means (AiR, AiG, AiB), and the deviation from reference wavelength 42\s, 42\,g, and Δλb as the wavelength deviation instruction values.

T=X+Y+Z (redescribed)

Then, the following expressions (expression 28) that are expressions to be solved in the feedback control loop in place of the above-described (expression 21) are obtained.

Δx=Jxr₀·ΔSr+Jxg₀·ΔSg+Jxb₀·ΔSb (Expression 280

Δy=Jyr₀·ΔSr+Jyg₀·ΔSg+Jyb_{i·ΔSb}

ΔY=Hyr₀·ΔSr+Hyg₀·ΔSg+Hyb₀·ΔSb

In this way, the variation of the color phase instruction values obtained when the light emission intensity instruction values for the respective wavelength bands are slightly varied can be represented by the linear operation with the use of the variation of the light emission intensity instruction values, and the coefficients at that time can be determined.

The values Δx, Δy, and ΔY on the left side of the expressions may be calculated by the above-described (expression 22), based on the target values xp, yp, and Yp of the chromaticity coordinates and the brightness instruction value Y and the values x, y, and Y at that time.

Also in the case where approximation in which the deviation from reference wavelength is approximated to zero is performed, one of the light emission intensity instruction values Sr, Sg, and Sb is eliminated from the (expression 28), and the feedback control to maintain only the chromaticity coordinates x, y to the target values may be performed, by using the same method described with reference to the above-described (expression 23).

Also in the case where the approximation in which the deviation from reference wavelength is approximated to zero is performed, the above-described (expression 3), (expression 4), and (expression 5) can be effectively used for determination of each of the total output power Pr of the drive circuits driving the light emitting elements in the R wavelength band, the total output power Pg of the drive circuits driving the light emitting elements in the G wavelength band, and the total output power Pb of the drive circuits driving the light emitting elements in the B wavelength band, among the above-described drive circuits (P1a, P1b, P2a, P2b, . . . ).

Namely, as described above, the integrating control circuit (Mc) applies the light emission intensity instruction values Sr, Sg, and Sb, calculated based on the band light characteristics acquisition data (ShR, ShG, ShB) obtained by the band light characteristics acquisition means (AiR, AiG, AiB), and the original target values Srp, Sgp, and Sbp to the (expression 4) to update the proportionality coefficients kr, kg, and kb.

After the variation ΔSr, ΔSg, and ΔSb are obtained by solving the above-described (expression 25) or (expression 28), the integrating control circuit (Mc) applies, with respect to the current values Sr, Sg, and Sb of the light emission intensity instruction values, the obtained variation ΔSr, ΔSg, and ΔSb to the (expression 5) to calculate new target values Srp, Sgp, and Sbp of the light emission intensity instruction values, and, thus, to update the total output power Pr, Pg, and Pb of the drive circuits (P1a, P1b, P2a, P2b, . . . ) according to the (expression 3).

The integrating control circuit (Mc) then returns to the operation of obtaining the band light characteristics acquisition data (ShR, ShG, ShB). Subsequently, the above-described sequence is repeated to build the feedback control loop.

Incidentally, the values of the tristimulus values X, Y, and Z on the left side of the expressions in the above-described (expression 24) are calculated by the above-described (expression 12), (expression 13), and (expression 14) after the light emission intensity instruction values Sr, Sg, and Sb, calculated based on the band light characteristics acquisition data (ShR, ShG, ShB) obtained by the band light characteristics acquisition means (AiR, AiG, AiB), and the deviation from reference wavelength Δλr, Δλg, and Δλb as the wavelength deviation instruction values, as described above. The values obtained by solving the above-described (expression 24) may be used as the light emission intensity instruction values Sr, Sg, and Sb to be applied to the above-described (expression 4) and (expression 5).

As described above, if the tristimulus values X, Y, and Z or the chromaticity coordinates x, y can be obtained, the coefficients of the above-described (expression 25) and (expression 28) that are linear equations for the feedback control may be determined by approximating all of the deviation from reference wavelength Δλr, Δλg, and Δλb to zero.

Inversely, this means that if there is band light characteristics acquisition means that can obtain the tristimulus values X, Y, and Z or the chromaticity coordinates x, y although it cannot obtain the deviation from reference wavelength Δλr, Δλg, and Δλb, the band light characteristics acquisition means can be used in the light source device of the present invention.

As such band light characteristics acquisition means (AiR, AiG, AiB), there can be adopted light quantity detectors for the respective wavelength bands configured such that in the spectral sensitivity characteristics, a sensitivity value at reference wavelength determined in each of the wavelength bands and the rate of sensitivity varying against wavelength varying match with a sensitivity value at reference wavelength of three color matching functions of an XYZ color system and the rate of sensitivity varying against wavelength varying.

This is because the above-described (expression 1) teaches that the tristimulus values X, Y, and Z can be measured by performing light quantity measurement with the use of an optical sensor having spectral sensitivity characteristics equal to the respective color matching functions xe(λ), ye(λ), and ze(λ). Accordingly, when the spectral sensitivity characteristics of the respective band light characteristics acquisition means (AiR, AiG, AiB) are the same as the respective color matching functions xe(λ), ye(λ), and ze(λ), the tristimulus values X, Y, and Z of the output luminous flux (Fo, Fo1, Fo2, . . . ) can be measured directly.

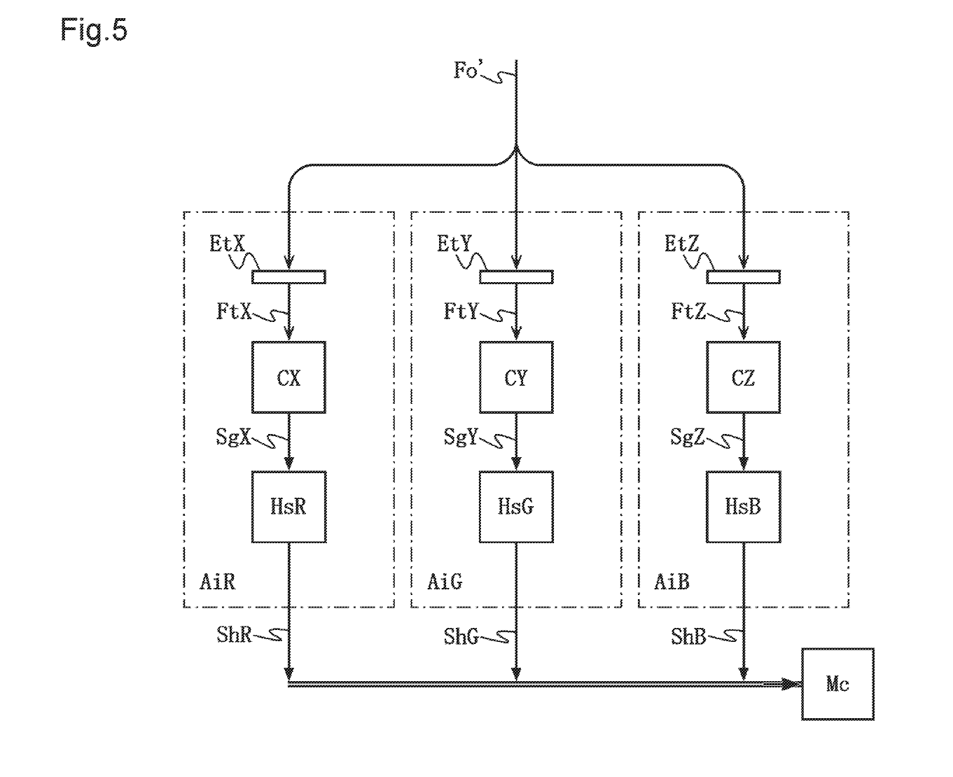

As shown in FIG. 5, which is a block diagram showing a portion of the light source device of the present invention in a simplified manner, in the band light characteristics acquisition means (AiR), the output luminous flux for measurement (Fo′) is input to a characteristics filter (EtX), an output luminous flux for measurement (FtX) transmitted therethrough is received by an optical sensor (CX).

A photodetection signal (SgX) from the optical sensor (CX) is subjected to necessary processing, such as amplification and AD conversion, by a signal processing circuit (HsR) to generate the band light characteristics acquisition data (ShR).

Naturally, in addition to the spectral sensitivity characteristics caused by the characteristics filter (EtX), the spectral sensitivity characteristics of the optical sensor (Cx) itself are reflected in the spectral sensitivity characteristics of the band light characteristics acquisition means (AiR).

The same applies to the band light characteristics acquisition means (AiG, AiB), and the band light characteristics acquisition means (AiG, AiB) are configured to include, instead of the characteristics filter (EtX), characteristics filters (EtY, EtZ) different in spectral sensitivity characteristics from the characteristics filter (EtX). At the rear stage subsequent to the characteristics filters (EtY, EtZ), an optical sensor (CY, CZ) receiving an output luminous flux for measurement (FtY, FtZ) and a signal processing circuit (HsG, HsB) processing a photodetection signal (SgY, SgZ) may be configured by using a same circuit section as the circuit section of the band light characteristics acquisition means (AiR) that is constituted of the optical sensor (CX) and the signal processing circuit (HsR). Also in the band light characteristics acquisition means thus configured, the band light characteristics acquisition data (ShG, ShB) can be generated.

Note that the signal processing circuits(HsR, HsG, HsB) may be integrated into a single signal processing circuit provided with an AD converter common to a multiplexer.

As described above, in order to make the spectral sensitivity characteristics of the respective band light characteristics acquisition means (AiR, AiG, AiB) equal to the respective color matching functions xe( ),), ye( ),), and ze( ),), in the spectral transmittance characteristics of the characteristics filters (EtX, EtY, EtZ), characteristics obtained by superimposing thereon the spectral sensitivity characteristics of the optical sensor (CX, CY, CZ) itself may be the same as the color matching functions xe( ),), ye( ),), and ze( ),).

Incidentally, in this light source device, since the light source device includes only the light emitting elements (Y1a, Y1b, Y2a, Y2b, . . . ) emitting light in a narrow wavelength band in the above-described wavelength band, it is only necessary to make the spectral sensitivity characteristics of the respective band light characteristics acquisition means (AiR, AiG, AiB) equal to the respective color matching functions xe(λ), ye(λ), and ze(λ) in at least the vicinity of the respective wavelength bands.

Accordingly, in the spectral transmittance characteristics of the characteristics filters (EtX, EtY, EtZ), the characteristics obtained by superimposing thereon the spectral sensitivity characteristics of the optical sensor (CX, CY, CZ) itself may be the same as the color matching functions xe( ),), ye( ),), and ze( ),) in at least the vicinity of the respective wavelength bands.

In order to make the spectral sensitivity characteristics equal to the color matching functions in the vicinity of the wavelength bands, approximation is further performed to determine the reference wavelength in each of the wavelength bands, and even if the sensitivity value at the reference wavelength and the rate of sensitivity varying against wavelength varying in the reference wavelength is the same as the function value in the reference wavelength in the above-described color matching function and the rate of function varying against wavelength varying in the reference wavelength, it is sufficiently practical.

Accordingly, in the spectral transmittance characteristics of the characteristics filters (EtX, EtY, EtZ), in the characteristics obtained by superimposing thereon the spectral sensitivity characteristics of the optical sensor (CX, CY, CZ) itself, a transmittance value in reference wavelength and the rate of transmittance varying against wavelength varying in the reference wavelength may be the same as the function value in the reference wavelength in the above-described color matching function and the rate of function varying against wavelength varying in the reference wavelength.

There will be considered a design in the case where the above-described wavelength band, that is, the band of the emission wavelength of the R, G, and B light emitting elements (Y1a, Y1b, Y2a, Y2b, . . . ) of this light source device is limited in a narrow range near reference wavelengths of 640 nm, 530 nm, and 465 nm, for example. At this time, the function value in the reference wavelength of the color matching function and the rate of function varying against wavelength varying are defined as the following expressions (expression 29), and numerical tables of the determined color matching functions xe(λ), ye(λ), and ze(λ) are referred to, whereby regarding the color matching function xe(λ) corresponding to the band light characteristics acquisition means (AiR), the following expressions (expression 30) is obtained.

λr₀=640 (Expression 29)

λg₀=530

λb₀=460

xe(λr₀=0.4479 (Expression 30)

xe(λg₀)=0.1655

xe(λb₀)=0.2511

dxe/dλ(λ=λr₀)=0.01742

dxe/dλ(λ=λg₀)=0.01204

dxe/dλ(λ=λb₀)=−0.01114

Further, regarding the color matching function ye( ),) corresponding to the band light characteristics acquisition means (AiG), the following expressions (expression 31) is obtained. Furthermore, regarding the color matching function ze(λ) corresponding to the band light characteristics acquisition means (AiB), the following expressions (expression 32) is obtained.

ye(λr₀)=0.1750 (Expression 31)

ye(λg₀)=0.8620

ye(λb₀)=0.0739

dye/dλ(λ=λr₀)=−0.00736

dye/dλ(λ=λg₀)=0.01058

dye/dλ(λ=λb₀)=0.00342

ze(λr₀)=0.0 (Expression 32)

ze(λg₀)=0.0422

ze(λb ₀)=1.5281

dze/dλ(λ=λr₀)=0.0

dze/dλ(λ=λg₀)=−0.00248

dze/dλ(λ−λb₀)=−0.04810

Accordingly, the characteristics filters (EtX, EtY, EtZ) may be produced so as to have spectral transmittances according to the respective (expression 30), (expression 31), and (expression 32).

In the characteristics filters, there may be determined characteristics within a bandwidth that is defined by an upper limit and a lower limit of the wavelength varying caused by fluctuation of the light emitting elements (Y1a, Y1b, . . . , Y2a, Y2b, . . . ) mounted near the wavelength determined by the above-described (expression 29), that is, mounted on this light source device and emission wavelength variation in the expected temperature range. The spectral transmittance characteristics outside the bandwidth do not matter.

Accordingly, since this filter is particularly easily designed/produced as compared with the filter used in a color meter or the like, the filter has an advantage that it can be achieved at low cost.

Here, as described above, a method of determining the target chromaticity coordinates, that is, the target value of the color phase instruction value will be described.

The light source device of the present invention is provided with an interface section (If) for obtaining data (Sxy) from outside and is configured such that, with respect to the result of applying the above-described output luminous flux (Fo, Fo1, Fo2, . . . ) to an external apparatus using this light source device, external data acquisition mode is executed to obtain color phase correlation data (Se) correlated with the color phase instruction value through the interface section (If). Namely, in the case where the external apparatus using the light source device is a projector, it is configured such that, with respect to an image projected on a screen by the projector performing two-dimensional optical amplitude modulation based on a video signal that is to become pure white by taking the output luminous flux (Fo, Fo1, Fo2, . . . ) of the light source device, the external data acquisition mode is executed to obtain a measurement value of the chromaticity coordinates through the interface section (If).

For example, initially, when this light source device supplies the output luminous flux (Fo, Fo1, Fo2, . . . ) to the projector while performing the feedback control such that the color of the output luminous flux is pure white (the chromaticity coordinates is ⅓, ⅓), the projector similarly projects a white color image based on the video signal that is to become pure white.

When it is assumed that a chromaticity coordinates measured value obtained when projection light of the white color image is measured by the color phase instruction value measuring means is x′, y′, if this coordinates are outside pure white, it is considered that this depends on a difference of light usage efficiency of an optical system of a projector body to the respective R, G, and B wavelength bands or mismatch in color correction performed against the difference by the projector.

With respect to the set light emission intensity instruction values Sr, Sg, and Sb in this light source device in the above-described pure white output state, it is assumed that the light emission intensity instruction values of light input to the color phase instruction value measuring means, that is, light output from the projector are αSr, βSg, and γSb.

Here, a, 13, and y represent the light usage efficiency in a broad sense of a projector optical system to the respective R, G, and B wavelength bands, including the above-described mismatch in color correction.

At this time, tristimulus values X′, Y′, and Z′ input to the color phase instruction value measuring means may be represented by the following expressions (expression 33) as in the above-described (expression 12).

X′=Hxr·α·Sr+Hxg·β·Sg+Hxb·γSb (Expression 33)

Y′=Hyr·α·Sr+Hyg·β·Sg+Hyb·γ·Sb

Z′=Hzr·α·Sr+Hzg·β·Sg+Hzb·γ·Sb

Accordingly, since it may be described as the following expression (expression 34) as in the above-described (expression 17), when the above-described (expression 33) and (expression 34) are applied to the following expressions (expression 35) corresponding to the above-described (expression 18) and arranged, the following expressions (expression 36) are obtained.

$${T}^{′} = {X}^{′} + {Y}^{′} + {Z}^{′} = Ir \cdot α \cdot Sr + Ig \cdot β \cdot Sg + Ib \cdot γ \cdot Sb \qquad ( Expression 34 )$$

x′·T′=X′ (Expression 35)

y′·T′=Y′

Ωxr·α·Sr+Ωxg·βSg+Ωxb·γ·Sb=0 (Expression 36)

Ωyr·α·Sr+Ωyg·β·Sg+Ωyb·γ·Sb=0

where

Ωxr=x′·Ir−Hxr

Ω/xg=x′·Ig−Hxg

Ωxb=x′·Ib−Hxb

Ωyr=y′·Ir−Hyr

Ωyg=y′·Ig−Hyg

Ωyb=y′·Ib−Hyb

Here, regarding α, β, and γ, the absolute values thereof are meaningless, and since only the ratios among them are meaningful, any of the values can be equal to 1 without losing generality. Therefore, if γ=1 here, the above-described (expression 36) may be described as the following expressions (expression 37).

Ωxr·Sr·α=Ωxg·Sg·β=−Ωxb·Sb (Expressin 37)

Ωyr·Sr·α=Ωyg·Sg·β=−Ωyb·Sb

As described above, chromaticity coordinates measured values are measured values x′, y′, the light emission intensity instruction values Sr, Sg, and Sb are set values inside this light source device, and Hxr, Hxg, Hzb, Ir, Ig, and lb are determined through the deviation from reference wavelength Δλr, Δλg, and Δλb. Therefore, since Ωxr, Ωxg, . . . , and Ωyb can be determined as values, the above-described (expression 37) can be easily solved because it is an elemental simultaneous linear equation with two unknowns a and (3.

As described above, since this light source device is in the state of performing the feedback control such that the color of the output luminous flux is pure white, if the chromaticity coordinates x, y are calculated by the above-described (expression 17) and (expression 18) with the use of the light emission intensity instruction values Sr, Sg, and Sb and the coefficients Hxr, Hxg, Hzb, Ir, Ig, and lb at that time, a value corresponding to pure white is naturally obtained.

When the chromaticity coordinates measured values x′, y′ are acquired to terminate the external data acquisition mode, this light source device solves the above-described (expression 37) to obtain a and 13 and, thus, to replace the light emission intensity instruction values Sr and Sg with Sr/α and Sg/β, respectively, divided by the broad light usage efficiency of a projector optical system to the respective wavelength bands, whereby the chromaticity coordinates xp, yp similarly calculated by the above-described (expression 17) and (expression 18) are set as a new target value to perform feedback control. Consequently, if the output luminous flux (Fo, Fo1, Fo2, . . . ) is generated, the chromaticity coordinates measured values x′, y′ of projected light of the white color image projected by a projector based on the video signal that is to become pure white become values close to values corresponding to pure white.

Thus, a balance of the light usage efficiency of an external apparatus using a light source device to each wavelength band, that is, α, β, and γ) is estimated by the color phase instruction value, calculated from the color phase correlation data (Se) obtained by execution of the external data acquisition mode, to the result of applying the output luminous flux (Fo, Fo1, Fo2, . . . ) to an external apparatus using a light source device, that is, the chromaticity coordinates measured values x′, y′. On that basis, it is possible to achieve setting of the target value of the color phase instruction value of the light source device, that is, the target chromaticity coordinates xp, yp so that the color phase instruction value relating to the result of applying the output luminous flux (Fo, Fo1, Fo2, . . . ) to the external apparatus using the light source device approaches the color phase instruction value desired, that is, ⅓, ⅓.

However, even if the target chromaticity coordinates xp, yp are obtained as described above, the chromaticity coordinates measured values x′, y′ of an image projected by a projector will not accurately match the value corresponding to pure white due to influences of various errors. Therefore, after that, it is preferable that pure white as a target is gradually achieved by repeating the following sequence for each measurement of the chromaticity coordinates measured values x′, y′. For example, there is repeated a sequence in which if x′ is more than ⅓, xp is reduced, and meanwhile if x′ is more than ⅓, xp is increased. Further, there is repeated a sequence in which if y′ is more than ⅓, yp is reduced, and meanwhile if y′ is more than ⅓, yp is increased.

Naturally, if there is no problem that time required for achieving the target is increased, the method of solving the above-described (expression 37) to obtain α and β may not be used, and control may be performed such that the above-described sequence is executed from the beginning.

The interface section (If) is a keyboard of an operation panel, for example, and the color phase instruction value measuring means is a color meter for general use. It may be configured such that the numerical values of the chromaticity coordinates measured values x′, y′ displayed in the color meter are input through operation of numerical keys of the keyboard. Alternatively, the interface section (If) is a communication interface transmitting and receiving digital data, for example, and may be configured such that the data (Sxy) of the chromaticity coordinates measured values x′, y′ is automatically input from the color meter in conjunction with measurement.

More preferably, an external apparatus using a light source device, such as a projector, incorporates color phase instruction value measuring means (Ae) and communicates the data (Sxy) of the chromaticity coordinates measured values x′, y′ with the light source device through the interface section (If). A system is configured to automatically measure/obtain the color phase correlation data (Se) in an appropriate timing when the system is started or during system operation and update a target value of the color phase instruction value.

In the above example, although there has been described a method of performing control such that based on a state in which a projector projects a white color image based on a video signal that is to become pure white, the target chromaticity coordinates xp, yp are set so as to correctly achieve this state, a state in which the projector projects an image in other chromaticity coordinates instead of pure white may be determined as a basic state, and control may be performed such that the target chromaticity coordinates xp, yp are set so as to correctly achieve this state.

In such case, it is preferable to configure such that the chromaticity coordinates determined as the basic state also can be obtained by this light source device through the interface section (If).

As the band light characteristics acquisition means of this light source device, although the band light characteristics acquisition means (AiR) for measuring the wavelength deviation instruction value with the use of the wavelength dispersibility optical element (Eg), as described in FIG. 3 has been described, the band light characteristics acquisition means applicable to the light source device of the present invention is not limited thereto.

The light source device of the present invention may be configured such that the band light characteristics acquisition means (AiR, AiG, AiB) of at least one of the above-described wavelength bands obtains first light quantity measurement data as the band light characteristics acquisition data (ShR, ShG, ShB) and second light quantity measurement data as the band light characteristics acquisition data (ShR, ShG, ShB), and the above-described light emission intensity instruction value and the above-described wavelength deviation instruction value are generated and obtained with the use of local band spectral sensitivity information. The band light characteristics acquisition means (AiR, AiG, AiB) is constituted of first light quantity measuring means (A1R, A1G, A1B) having first spectral sensitivity characteristics relating to the spectral sensitivity characteristics in the relevant wavelength band and second light quantity measuring means (A2R, A2G, A2B) having second spectral sensitivity characteristics. Here, in the first spectral sensitivity characteristics and the second spectral sensitivity characteristics, the rate of sensitivity varying against wavelength varying, that is, gradient of sensitivity varying at the time of wavelength varying are different. The local band spectral sensitivity information includes sensitivity values at reference wavelength of the first spectral sensitivity characteristics in the relevant wavelength band and the second spectral sensitivity characteristics and the rate of sensitivity varying against wavelength varying, and the local band spectral sensitivity information is possessed by the band light characteristics acquisition means (AiR, AiG, AiB).

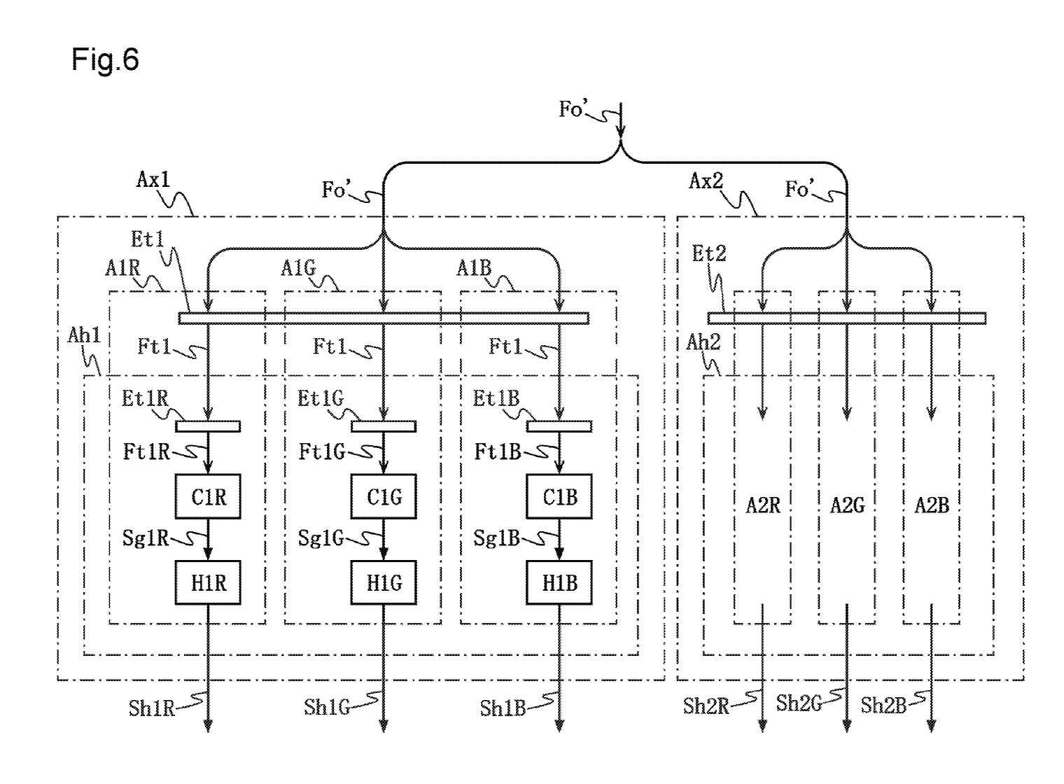

An example of configuration of the first light quantity measuring means (A1R, A1G, A1B) will be described using FIG. 6, which is a block diagram showing a portion of the light source device of the present invention in a simplified manner

In the light source device of this invention, although the band light characteristics acquisition means (AiR, AiG, AiB) of at least one of the above-described wavelength bands is constituted of the first light quantity measuring means having the first spectral sensitivity characteristics relating to the spectral sensitivity characteristics in the relevant wavelength band and the second light quantity measuring means having the second spectral sensitivity characteristics, in this embodiment the light source device is illustrated while assuming that the band light characteristics acquisition means (AiR, AiG, AiB) of all the wavelength bands are configured as described above.

Accordingly, in the light source device illustrated in this drawing, the output luminous flux for measurement (Fo′) is input to the first light quantity measuring means (A1R, A1G, A1B) provided for each of the above-described wavelength bands, and the same output luminous flux for measurement (Fo′) is input to the second light quantity measuring means (A2R, A2G, A2B) provided for each of the above-described wavelength bands.

In this drawing, as a mere matter of convenience, a set of the first light quantity measuring means (MR, A1G, A1B) of the respective R, G, and B wavelength bands is illustrated as a first light quantity measuring means group (Δxi), and a set of the second light quantity measuring means (A2R, A2G, A2B) of the respective R, G, and B wavelength bands is illustrated as a second light quantity measuring means group (Δx2). For example, the first light quantity measuring means of R color and the second light quantity measuring means of R color may be collected, the first light quantity measuring means of G color and the second light quantity measuring means of G color may be collected, and the first light quantity measuring means of B color and the second light quantity measuring means of B color may be collected.

Further, in this drawing, although light beams divided from the output luminous flux for measurement (Fo′) obtained by gathering luminous fluxes extracted partially from the output luminous fluxes (Fo1, Fo2, . . . ) of the respective wavelength bands is input to the band light characteristics acquisition means (AiR, AiG, AiB), the luminous fluxes may not be gathered, and the output luminous flux for measurement for each wavelength band may be input directly to the band light characteristics acquisition means (AiR, AiG, AiB) for the respective wavelength bands.

In the first light quantity measuring means (A1R, A1G, A1B), the output luminous flux for measurement(Fo′) is input to a characteristics filter (Ea). Output luminous fluxes for measurement (Ftl) passing through the characteristics filter (Ea) are input to band filters (Et1R, Et1G, Et1B) of three colors of R, G, and B. Output luminous fluxes for measurement (Ft1R, Ft1G, Ft1B) passing through the band filters (Et1R, Et1G, Et1B) are received by optical sensors (C1R, C1G, C1B) for each color.

Photodetection signals (Sg1R, Sg1G, Sg1B) from the optical sensors (C1R, C1G, C1B) are subjected to necessary processing, such as amplification and AD conversion, by signal processing circuits (H1R, H1G, H1B) to generate first light quantity measurement data (Sh1R, Sh1G, Sh1B) formed of information on light quantity in the respective R, G, and B wavelength bands.

Naturally, in addition to the spectral sensitivity characteristics caused by the characteristics filter (Ea) and the band filters (Et1R, Et1G, Et1B), the spectral sensitivity characteristics of the optical sensors (C1R, C1G, C1B) itself are reflected in the spectral sensitivity characteristics of the band light characteristics acquisition means (AiR, AiG, AiB).

Note that although it is described that the characteristics filter (Ea) shared by the first light quantity measuring means (A1R, A1G, A1B) is provided, individual characteristics filters may be provided to the respective first light quantity measuring means (A1R, A1G, A1B).

Further, although it is described that the signal processing circuits (H1R, H1G, H1B) are provided to the respective photodetection signals (Sg1R, Sg1G, Sg1B), after an analog multiplexer selecting one of the photodetection signals (Sg1R, Sg1G, Sg1B) according to a selection signal is provided, the signal processing circuit may be provided commonly to the photodetection signals (Sg1R, Sg1G, Sg1B).

The same applies to the second light quantity measuring means (A2R, A2G, A2B). The second light quantity measuring means (A2R, A2G, A2B) may include, in place of the characteristics filter (Ea), a characteristics filter (Et2) different in spectral sensitivity characteristics from the characteristics filter (Ea). An optical sensor circuit section (Ah2) on the rear stage subsequent to the characteristics filter (Et2) may be configured using a same optical sensor circuit section as the optical sensor circuit section (Ahl) of the first light quantity measuring means (A1R, A1G, A1B) that is constituted of the band filters (Et1R, Et1G, Et1B), the optical sensors (C1R, C1G, C1B), and the signal processing circuits (H1R, H1G, H1B). In the optical sensor circuit section thus configured, second light quantity measurement data (Sh2R, Sh2G, Sh2B) can be generated.

Then, the integrating control circuit (Mc) can read the first light quantity measurement data (Sh1R, Sh1G, Sh1B) and the second light quantity measurement data (Sh2R, Sh2G, Sh2B).

Naturally, the characteristics filter (Ea) and the band filters (Et1R, Et1G, Et1B) of the first light quantity measuring means (A1R, A1G, A1B) may not be separated, and each of the band filters (Et1R, Et1G, Et1B) may be configured to further have a function of the characteristics filter (Ea). The same applies to the band filters of the second light quantity measurement means (A2R, A2G, A2B).

In addition, the characteristics filter of one of the first light quantity measuring means (A1R, A1G, A1B) and the second light quantity measuring means (A2R, A2G, A2B) may be transparent.

Further, naturally, as described with reference to FIG. 1 above, in the case where the output luminous fluxes (Fo1, Fo2, . . . ) are used independently for each of R, G, and B colors, each of the optical sensors (C1R, C1G, C1B) is not collectively mounted in the optical sensor circuit section (Ahl) but may be configured separately.

Regarding the first spectral sensitivity characteristics of the first light quantity measuring means (A1R, A1G, A1B) and the second spectral sensitivity characteristics of the second light quantity measuring means (A2R, A2G, A2B) for each of the R, G, and B wavelength bands, it is sufficient to achieve a state in which the rate of sensitivity varying against wavelength varying, that is, gradient of sensitivity varying at the time of wavelength varying are different in each of the wavelength bands. Specifically, when (expression 41), (expression 42), and (expression 43) described later are regarded as simultaneous linear equation with two unknowns relating to Sr and Δλr, Sg and Sg·Δλg, and Sb and Sb.Δλb, respectively, it is sufficient to achieve a state in which a determinant of each expression is not zero.

In this case, the spectral sensitivity characteristics indicate a set of the spectral sensitivity characteristics of the R-color wavelength band, the spectral sensitivity characteristics of the G-color wavelength band, and the spectral sensitivity characteristics of the B-color wavelength band.

Incidentally, examples of a case of difference of the rate of sensitivity varying against wavelength varying in one wavelength band may include a case in which one of the first spectral sensitivity characteristics and the second spectral sensitivity characteristics is positive and the other is negative, one of them is substantially zero and the other is not zero (a finite value), and a case where both of them have the same symbol but the absolute values thereof are different from each other. Any case may be possible.

Restriction of the rate of sensitivity varying against wavelength varying is limited to within a bandwidth that is defined by an upper limit and a lower limit of the wavelength varying caused by fluctuation of the light emitting elements (Y1a, Y1b, . . . , Y2a, Y2b, . . . ) mounted on this light source device and emission wavelength variation in the expected temperature range. The spectral sensitivity characteristics outside the bandwidth do not matter.

When, out of the light emitting elements (Y1a, Y1b, . . . , Y2a, Y2b, . . . ), the light emitting elements used for one wavelength band are unified to the same products manufactured by the same manufacturer, the bandwidth is usually about several nanometer to about ten nanometer. However, regarding the first spectral sensitivity characteristics and the second spectral sensitivity characteristics, variation of the rate of sensitivity varying against wavelength varying in the bandwidth may be desirably small.

The integrating control circuit (Mc) has local band spectral sensitivity information that is configured of the sensitivity value at reference wavelength and the rate of sensitivity varying against wavelength varying for each of the R, G, and B wavelength bands, regarding each of the first spectral sensitivity characteristics and the second spectral sensitivity characteristics.

Accordingly, as will be described later, the integrating control circuit (Mc) uses the local band spectral sensitivity information to approximately calculate the light emission intensity instruction values correlated with the light intensity and the wavelength deviation instruction values correlated with the deviation from reference wavelength for the respective R, G, and B wavelength bands, based on the first light quantity measurement data (Sh1R, Sh1G, Sh1B) read from the first light quantity measuring means (A1R, A1G, A1B) and the second light quantity measurement data (Sh2R, Sh2G, Sh2B) read from the second light quantity measuring means (A2R, A2G, A2B).

Hereinafter, there will be described a method of calculating the light emission intensity instruction values and the deviation from reference wavelength that is the wavelength deviation instruction values based on the first light quantity measurement data (Sh1R, Sh1G, Sh1B) and the second light quantity measurement data (Sh2R, Sh2G, Sh2B) obtained by measuring luminous flux to be measured, represented by spectrum S(λ) having a wavelength λ as a parameter, with the use of the first light quantity measuring means (A1R, A1G, A1B) and the second light quantity measuring means (A2R, A2G, A2B).

When the first light quantity measuring means (A1R, A1G, A1B) include respective spectral sensitivity characteristics rm(λ), gm(λ), and bm(λ) in the respective R, G, and B wavelength bands, light quantity measurement data values Rm, Gm, and Bm in the respective R, G, and B wavelength bands included in the first light quantity measurement data (Sh1R, Sh1G, Sh1B) are represented by the following expressions (expression 38).

Rm=∫S(λ)·m(λ)·dλ (Expression 38)

Gm=∫S(λ)·gm(λ)·gm(λ).

Bm=∫S(λ)·bm(λ0·bλ

Likewise, when the second light quantity measuring means (A2R, A2G, A2B) include respective spectral sensitivity characteristics rn( λ), gn(λ), and bn(λ) in the respective R, G, and B wavelength bands, light quantity measurement data values Rn, Gn, and Bn in the respective R, G, and B wavelength bands included in the second light quantity measurement data (Sh2R, Sh2G, Sh2B) are represented by the following expressions (expression 39).

Rn=∫S9λ)·m(λ)·dλ (Expression 39)

Gn=∫S(λ)·gn(λ)·dλ

Bn=∫S(λ0·bn·(λ)·dλ

Note that these integration regions cover the respective wavelength bands in which spectrum of at least the luminous flux to be measured S(λ) exists.

Here, when the luminous flux to be measured S(λ) is approximated to be formed of three primary colors R, G, and B, the luminous flux to be measured S(λ) is represented by the above-described (expression 11), that is, the following expression (redescribed) with the use of the delta function δ(λ.

$$S ( λ ) = Sr \cdot δ ( λ - λ {r}_{0} - Δλ r ) + Sg \cdot δ ( λ - λ {g}_{0} - Δλg ) + Sb \cdot δ ( λ - λ {b}_{0} - Δλ b ) \qquad ( Expression 11 )$$

where, the reference wavelengths of R, G, and B are denoted by λro, λgo, and kilo, respectively, the deviation from reference wavelength as the wavelength deviation instruction values are denoted by Δλr, Δλg, and Δλb, respectively, and the light emission intensity instruction values of the respective R, G, and B wavelength bands are denoted by Sr, Sg, and Sb, respectively.

Typically, variation Af in the function f=f(λ) when the variable λ of the function f is slightly varied by Aλ may be approximated by the above-described (expression 7), that is, the following expression (redescribed) with the use of the derivative df/dλ, of the function f.

Δf=(df/dλ)·Δλ (Expression 7)

Accordingly, when the variable λ is represented by λ=λro+Δλr in the case where the variable λ is in the vicinity of λro, the spectral sensitivity characteristics are represented by the following expressions (expression 40).

rn(λ)=rm(λr₀+Δλr)=rm(λr₀)+Erm₀·Δλr (Expression 40)

rn(λ)=rn(λr₀+Δλr)=rn(λr₀)+Ern₀·Δλr

where, Ermo and Erno are values when the variable λ in the derivative of rm(λ) and rn(λ) is λro.

When the above-described (expression 11) and (expression 40) are applied to the first expression of the above-described (expression 38) and (expression 39), the following expressions (expression 41) are obtained.

$$Rm = Sr \cdot \int δ ( λ - λ {r}_{0} - Δλ r ) \cdot rm ( λ ) \cdot d λ = Sr \cdot rm ( λ {r}_{0} + Δλ r ) = Sr \cdot [ rm ( λ {r}_{0} ) + {Erm}_{0} \cdot Δλ r ] \\ Rn = Sr \cdot [ rn ( λ {r}_{0} ) + {Ern}_{0} \cdot Δλ r ] \qquad ( Expression 41 )$$

where,

Erm₀=drm/dλ(λ=λr₀)

Ern₀=drn/dλ(λ=λr₀)

These expressions are rewritten in the following manner, and as seen from the rewritten expressions, these expressions are simultaneous linear equation with two unknowns relating to Sr and Sr·Δλr. Therefore, the expressions are solved by elemental calculation to obtain the values Sr and Sr·Δλr, that is, the values Sr and Δλr.

Rm=rm(λr₀)·Sr+Erm₀·Sr·Δλr

Rn=rn(λr₀)·Sr+Ern₀·Sr·Δλr

Likewise, when the variable λ is represented by k=λgo+Δλg in the case where the variable λ is in the vicinity ofΔλg, the following expressions (expression 42) are obtained.

Gm=Sg·[gm(λ·g₀0+Egm₀·Δλg] (Expression 42)

Gn=Sg·[gn(λg₀)+Egn₀·Δλg]

where,

Egm₀=dgm/dλ(λ=g₀)

Egn₀=dgn/dλ(λ=λg₀)

Further, when the variable λ is represented by λ=λb+Δλb in the case where the variable λ is in the vicinity of kilo, the following expressions (expression 43) are obtained. Accordingly, it is possible to obtain the values Sg and Δλg and the values Sb and Δλb therefrom.

Bm=Sb·[bm(λb₀)+Ebm₀·Δλb] (Expression 430

Bn=Sb·[bn(λb₀)+Ebn₀·Δλb]

where,

Ebm₀=dbm/dλ(λ=λb₀)

Ebn₀=dbn/dλ(λ=λb₀)

Determination of the light emission intensity instruction values Sr, Sg, and Sb and the deviation from reference wavelength Δλr, Δλg, and Δλb as the wavelength deviation instruction values, based on the light quantity measurement data values Rm, Gm, and Bm measured with the use of the first light quantity measuring means (A1R, A1G, A1B) and the light quantity measurement data values Rn, Gn, and Bn measured with the use of the second light quantity measuring mean (A2R, A2G, A2B), is summarized as follows.

The local band spectral sensitivity information relating to the first light quantity measuring means (A1R, A1G, A1B), that is, the values rm(λro), gm(λgn), and bm(kbn) of the spectral sensitivity characteristics rm(λ), gm(λ), and bin(λ) at the reference wavelengths λro, λgo, and kilo of the respective R, G, and B wavelength bands and the values Ermo, Egmo, and Ebmo of the rate of sensitivity varying against wavelength varying of the spectral sensitivity characteristics, the local band spectral sensitivity information relating to the second light quantity measuring means (A2R, A2G, A2B), that is, the values m(λro), gn(λgn), and bn(kbn) of the spectral sensitivity characteristics rn(λ), gn(λ), and bn(λ) at reference wavelengths km, λgo, and kilo of the respective R, G, and B wavelength bands and the values Erno, Egno, and Ebno of the rate of sensitivity varying against wavelength varying of the spectral sensitivity characteristics are prepared in advance.

Then, when the light quantity measurement data values Rm, Gm, Bm by the first light quantity measurement means (A1R, A1G, A1B) and the light quantity measurement data values Rn, Gn, and Bn by the second light quantity measurement means (A2R, A2G, A2B) are obtained, it is possible to easily determine the light emission intensity instruction values Sr, Sg, and Sb and the deviation from reference wavelength Δλr, Δλg, and Δλb as the wavelength deviation instruction values, from the solution of the above-described (expression 41), (expression 42), and (expression 43).

As described in FIGS. 5 and 6 hereinabove, although the method of obtaining the deviation from reference wavelength Δλr, Δλg, and Δλb with the use of an imaging element and an optical sensor, as described regarding the background art, the light emitting element constituted of a semiconductor laser and so on can achieve a simply configured, that is, low cost band light characteristics acquisition means with the use of property in which the emission wavelength is varied by an environmental temperature change or temperature increase due to self heating.

Namely, it is configured such that the band light characteristics acquisition means (AiR, AiG, AiB) is provided with a light quantity detector detecting the light quantity of the output luminous flux for measurement (Fo′) received and a temperature detector detecting the temperature of the light emitting element to generate the band light characteristics acquisition data (ShR, ShG, ShB), and the integrating control circuit (Mc) estimates the above-described wavelength deviation instruction value based on the detected temperature of the light emitting element.

The band light characteristics acquisition means is provided with, regarding one wavelength band, the temperature detector detecting the temperature of the light emitting element supplying light in the relevant wavelength band in addition to the light quantity detector detecting the light quantity of the output luminous flux for measurement (Fo′) and generates the band light characteristics acquisition data so that light quantity data detected by the light quantity detector and temperature data detected by the temperature detector are included. Meanwhile, the integrating control circuit (Mc) is configured to hold correlation data between the temperature of the light emitting element and variation of an emission wavelength. Consequently, the integrating control circuit (Mc) can obtain, regarding the relevant wavelength band, a light emission intensity instruction value correlated with light intensity and an estimated wavelength deviation instruction value correlated with deviation from reference wavelength based on the band light characteristics acquisition data obtained from the band light characteristics acquisition means.

Naturally, the light quantity detector and the temperature detector constituting the band light characteristics acquisition means may not be integrally configured.

The light emitting element is configured to be in thermal contact with and hold a heat sink provided with a cooling mechanism of air cooling type, water cooling type, or an electrical type according to a Peltier element and so on, for releasing a self-heating amount due to energization. Preferably, a groove is provided at a portion on the light emitting element side or the heat sink side of a surface in contact with the light emitting element and the heat sink, and the temperature detector is stored in this groove.

As the temperature detector, a thermistor, a thermocouple, a semiconductor temperature sensor, or the like may be used.

Note that there is one or a plurality of the light emitting elements belonging to one wavelength band, and when a plurality of the temperature detectors are provided, as the simplest configuration, according to the reason described about the variation of the emission wavelength, an integrated wavelength deviation instruction value can be estimated by calculating an average value of respective temperatures detected by the temperature detector.

Incidentally, when power of light emitting elements for which the respective temperature detectors serve temperature detection differ for each temperature detector, it is preferable that an integrated wavelength deviation instruction value is calculated by weighted average calculation in which the wavelength deviation instruction value estimated based on the temperature detected by the temperature detector is weighted by a quantity correlated with the power of the light emitting element in charge, for example, a current value.

As described above, since a main factor of a temperature change of a light emitting element is a temperature increase due to self heating caused by power projected from the drive circuit, while focusing attention on correlation of the temperature increase with the power projected to the light emitting element, it is possible to achieve a more simply configured, that is, lower cost band light characteristics acquisition means.

Namely, it is configured such that the band light characteristics acquisition means (AiR, AiG, AiB) is provided with the light quantity detector measuring the light quantity of the output luminous flux for measurement (Fo′) received and power detector detecting a quantity correlated with power projected to the light emitting element to generate the band light characteristics acquisition data (ShR, ShG, ShB), and the integrating control circuit (Mc) estimates the above-described wavelength deviation instruction value based on the detected power projected to the light emitting element.

The band light characteristics acquisition means is provided with, regarding one wavelength band, the power detector detecting power of the light emitting element supplying light in the relevant wavelength band in addition to the light quantity detector detecting the light quantity of the output luminous flux for measurement (Fo′) and generates the band light characteristics acquisition data so that light quantity data detected by the light quantity detector and power data detected by the power detector are included. Meanwhile, the integrating control circuit (Mc) is configured to hold correlation data between the power of the light emitting element and variation of an emission wavelength. Consequently, the integrating control circuit (Mc) can obtain, regarding the relevant wavelength band, a light emission intensity instruction value correlated with light intensity and an estimated wavelength deviation instruction value correlated with deviation from reference wavelength based on the band light characteristics acquisition data obtained from the band light characteristics acquisition means.

Naturally, the light quantity detector and the power detector constituting the band light characteristics acquisition means may not be integrally configured.

Note that as described above, the drive circuits (P1a, P1b, P2a, P2b, . . . ) each have a function of performing control such that predetermined power can be projected to the light emitting elements (Y1a, Y1b, Y2a, Y2b, . . . ). Thus, when power detecting means for detecting power projected to the light emitting element driven by the drive circuit is provided, the power detecting means can serve the power detector for obtaining the wavelength deviation instruction value.

Accordingly, at this time, the drive circuit (P1a, P1b, P2a, P2b, . . . ) serve some functions of the band light characteristics acquisition means (AiR, AiG, AiB), and the integrating control circuit (Mc) receives a portion of the band light characteristics acquisition data (ShR, ShG, ShB) from the drive circuits (P1a, P1b, P2a, P2b, . . . ) through the drive circuit control signals (J1a, J1b, J2a, J2b, . . . )

Naturally, since a current value flowing to the light emitting element and a voltage value generated when a current flows are correlated with the power projected to the light emitting element, the current value and the voltage value can be substituted as a value of power detected for acquisition of the wavelength deviation instruction value.

Since the emission wavelength of the light emitting element is varied by an environmental temperature in addition to the self-heating amount, a temperature detector detecting the environmental temperature is further provided, and an estimated wavelength deviation instruction value based on power can be corrected by the detected temperature.

When values of detected power of the light emitting elements differ from each other, if a correlation between a power value and a wavelength deviation instruction value is linear, an integrated wavelength deviation instruction value may be estimated by an average value of detected power values. Meanwhile, if the correlation is not linear, it is preferable that the integrated wavelength deviation instruction value is calculated by weighted average calculation in which the wavelength deviation instruction value estimated based on the detected power values is weighted by the detected power value.

In the band light characteristics acquisition means for estimating the wavelength deviation instruction value from the temperature of the light emitting element and the band light characteristics acquisition means for estimating the wavelength deviation instruction value from the power of the light emitting element, the light quantity detector is required to be provided in addition to the temperature detector or the power detector, as described above.

As the light quantity detector, an imaging element may be used in addition to a light quantity detector detecting the magnitude of a light quantity.

In particular, in an imaging element for color photographing, R, G, and B color filters are provided in each pixel. Therefore, advantageously, even if the output luminous flux for measurement (Fo′) is white color light in which R, G, and B are mixed, a spectral filter is not required to be added, and light quantity data of the respective R, G, and B wavelength bands can be generated by a single imaging element.

The configuration in which light is transmitted with the use of the optical fiber has been described with reference to FIG. 2. Since the optical fiber is formed of fragile glass such as quartz, the optical fiber disadvantageously has a risk of breakage.

If the optical fiber is broken, optical power is leaked from the broken part and leaked optical power is absorbed by a covering material provided to mechanically protect the optical fiber, which may cause burning out of the covering material. Therefore, safety measures that detect breakage of the optical fiber and turn off the light emitting elements are necessary.

When large power is transmitted as a whole, the optical power is divided and transmitted by a plurality of optical fibers, which is advantageous in terms of configuration of the optical system and safety even if the light has the same color. In such a case, desirably, the light quantity per one optical fiber may be monitored in addition to the integral light quantity from all of the optical fibers, and breakage of the optical fiber may be detected individually.

As described above, in the case where the exit ends (Eo1, Eo2, . . . ) of the respective optical fibers (Ef1, Ef2, . . . ) are bundled such that the exit ends are aligned so as to be positioned on the same plane, an image on a plane at which the exit ends (Eo1, Eo2, . . . ) are positioned is projected to the imaging element with the use of a lens or the like, whereby it is possible to identify each optical fiber and to monitor the light quantity, and it is thus possible to detect breakage of the optical fiber individually.

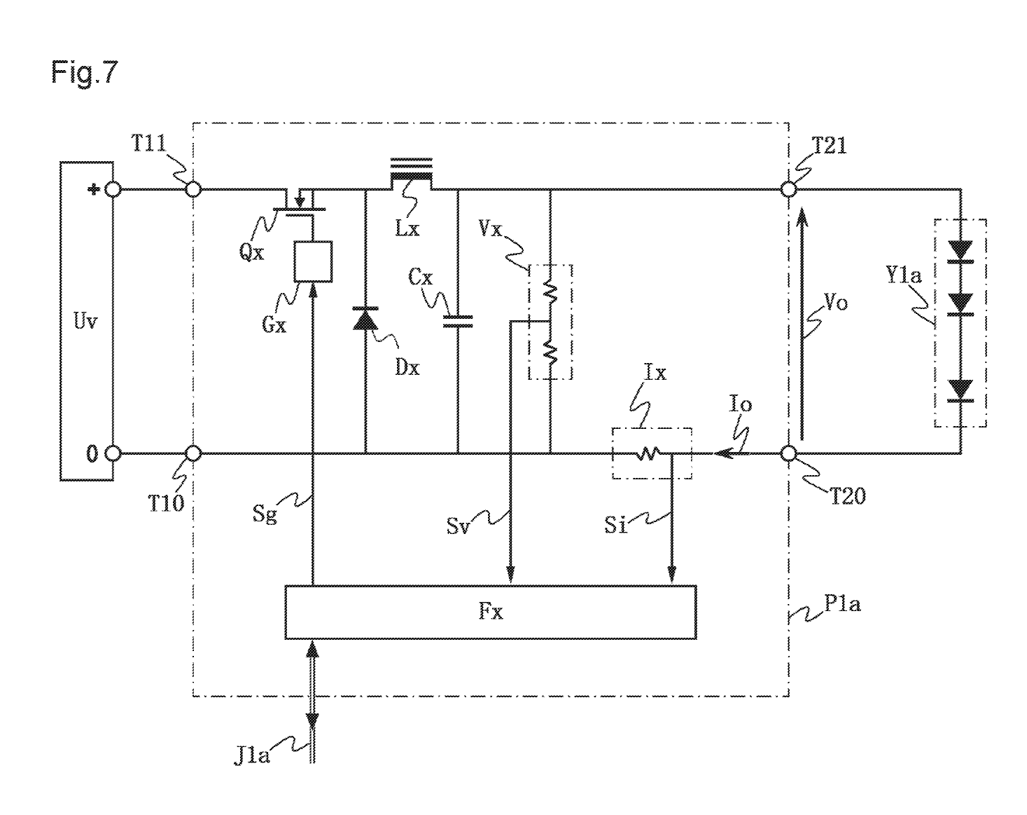

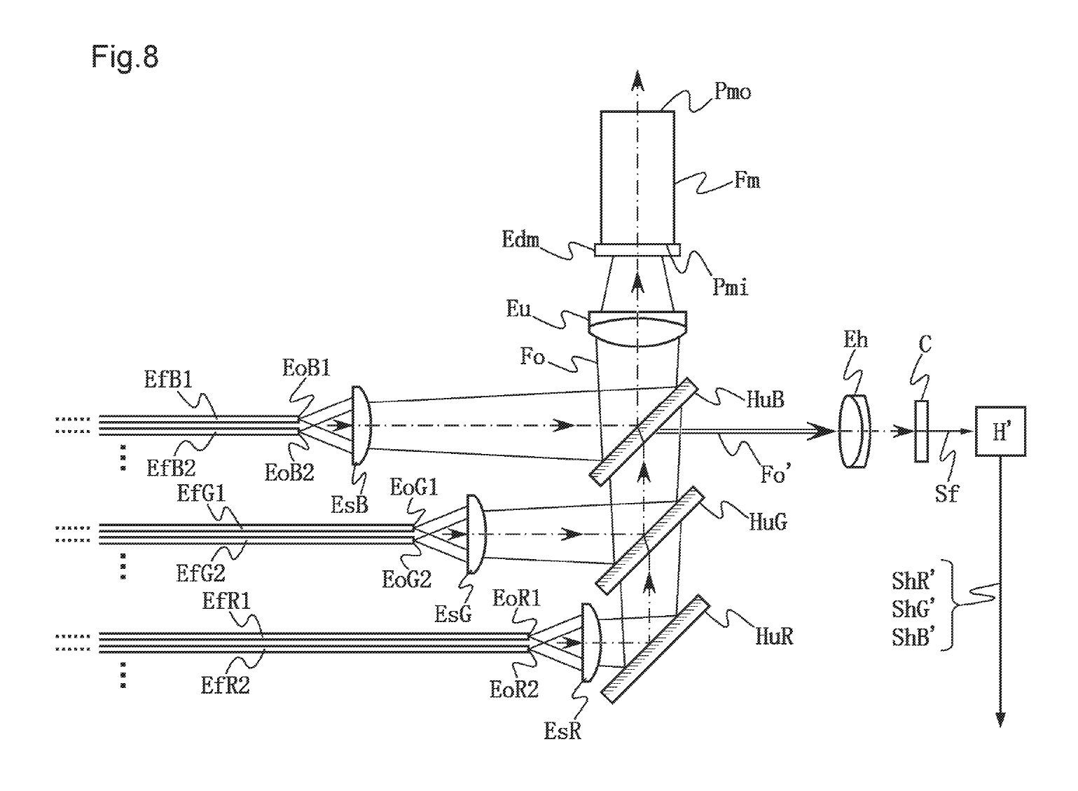

Next, with reference to FIGS. 7 and 8 that are each a schematic diagram showing one mode of a portion of an embodiment of the light source device of the present invention in a simplified manner, specific configuration of the drive circuit of the light source device of the present invention and specific configuration of the optical fibers and subsequent to the exit ends of the optical fibers in a projector of the present invention using the light source device of the present invention will be described as modes for practicing the present invention.

The drive circuit (P1a) described in FIG. 7 shows an example of a configuration embodied by exemplifying one of the drive circuits (P1a, P1b, P2a, P2b, . . . ) of the light source device of the present invention.

The drive circuit (P1a) based on a step-down chopper circuit is operated by receiving supply of voltage from a DC power supply (Uv) connected to nodes (T10, T11) and adjusts an amount of power supplied to the light emitting element (Y1a).

Note that it is assumed here that the light emitting element (Y1a) is configured by connecting a plurality of semiconductor lasers in series.

In the drive circuit (P1a), turning on and off of current from the DC power supply (Uv) is switched by a switching element (Qx) such as FET, and a smoothing capacitor (Cx) is charged through a choke coil (Lx). It is configured such that this voltage is applied from the nodes (T20, T21) to the light emitting element (Y1a) to allow current to flow to the light emitting element (Y1a).

Note that, in a period when the switching element (Qx) is in an on-state, the smoothing capacitor (Cx) is directly charged and current is supplied to the light emitting element (Y1a) which is a load, by the current which flows through the switching element (Qx), and, at the same time, energy is stored in the choke coil (Lx) in the form of magnetic flux. Meanwhile, in a period when the switching element (Qx) is in an off-state, current is supplied to the light emitting element (Y1a) through a fly wheel diode (Dx), by the energy stored in the choke coil (Lx) in the form of magnetic flux and electric discharge from the smoothing capacitor (Cx).

In the step down chopper type drive circuit (P1a), the amount of power supplied to the light emitting element (Y1a) can be adjusted by a ratio of a period of an ON state of the switching element (Qx) to an operation cycle of the switching element (Qx), that is, a duty cycle ratio.

Here, a gate driving signal (Sg) having a certain duty cycle ratio is generated by a drive control circuit (Fx), and turning on and off of current from the DC power supply (Uv) is controlled by controlling a gate terminal of the switching element (Qx) through a gate drive circuit (Gx).

It is configured such that an output current Io flowing to the light emitting element (Y1a) can be detected by output current detecting means (Ix), and the output current detecting means (Ix) can be easily realized by using a shunt resistor. It is configured such that an output voltage Vo applied to the light emitting element (Y1a) can be detected by output voltage detecting means (Vx), and the output voltage detecting means (Vx) can be easily realized by using a voltage dividing resistor.

An output current signal (Si) and an output voltage signal (Sv) detected respectively by the output current detecting means (Ix) and the output voltage detecting means (Vx) are read by the drive control circuit (Fx).

The drive control circuit (Fx) transmits and receives data to and from the integrating control circuit (Mc) through a drive circuit control signal (Jla) and holds a target value of power projected to the light emitting element (Y1a) or a target value of current flowing to the light emitting element (Y1a), that is correlated with power. A value of power of the light emitting element (Y1a) measured based on the output current signal (Si) and the output voltage signal (Sv) (this value is calculated based on the product of the output current signal (Si) and the output voltage signal (Sv)) or a value of current and the above-described target value are compared, and the above-described duty cycle ratio is subjected to feedback control such that the difference between the value of power or current of the light emitting element (Y1a) and the target value is reduced.

The integrating control circuit (Mc) reads the value of power or current of the light emitting element (Y I a) through the drive circuit control signal (Jla) and uses the value as a quantity for obtaining the above-described wavelength deviation instruction value.

Meanwhile, FIG. 8 shows the configuration of the optical fibers and subsequent to the exit ends of the optical fibers in the projector of the present invention.

In the light source device, a plurality of optical fibers for each of the three primary colors of R, G, and B, that is, optical fibers for R light source (EfR1, EfR2, . . . ), optical fibers for G light source (EfG1, EfG2, . . . ), and optical fibers for B light source (EfB1, EfB2, . . . ) are configured as a fiber bundle whose respective exit ends are aligned and bundled. Luminous fluxes emitted from the exit ends of the three fiber bundles and converted into infinite images by respective collimator lenses (EsR, EsG, EsB) are color-synthesized with the use of a mirror (HuR) and dichroic mirrors (HuG, HuB) to generate the output luminous flux (Fo) of the light source device.

The output luminous flux (Fo) enters a focusing lens (Eu), and the focused output luminous flux is then input to an incident end (Pmi) of homogenizing means (Fm) that is configured of a rod integrator, through a diffusion element (Edm) for removing speckles.

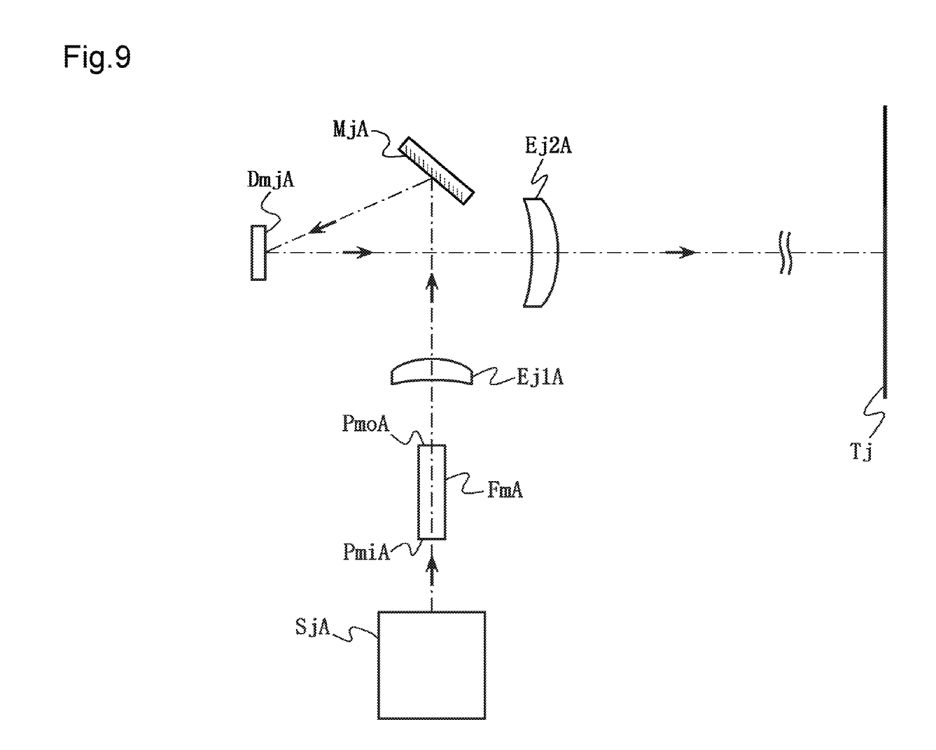

The optical system subsequent to an emission end (Pmo) of the homogenizing means (Fm) is similar to that described with reference to FIG. 9 described above.

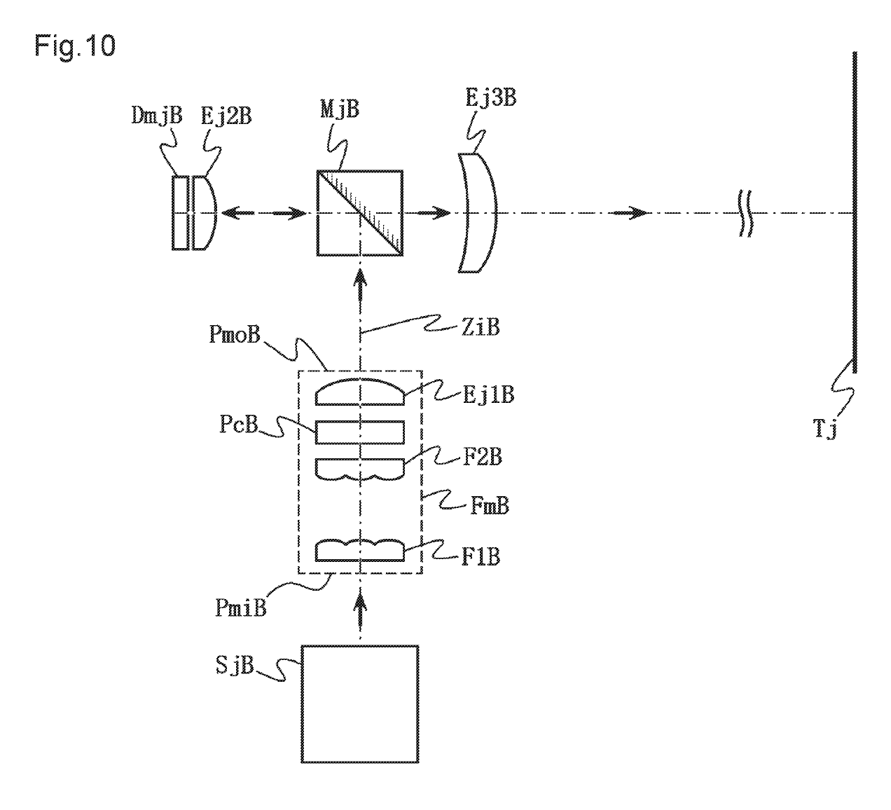

Naturally, the light source device of the present invention may be used in a projector that uses a homogenizing means configured of a fly eye integrator, described with reference to FIG. 10 described above.

The dichroic mirror (HuB) is so fabricated as to allow light of colors R and G to pass therethrough as much as possible and as to reflect light of B color as much as possible. However, reflected light of colors R and G and transmitted light of color B exist to no small extent. Although such light is usually discarded as stray light, in the light source device in FIG. 8, such light is effectively used to obtain the output luminous flux for measurement (Fo′).

The output luminous flux for measurement (Fo′) enters an imaging optical system (Eh) configured of a lens, and an actual image that is conjugate with R exit ends (EoR1, EoR2, . . . ), G exit ends (EoG1, EoG1 . . . ), and B exit ends (EoB1, EoB2, . . . ) of the fiber bundles is formed on an imaging surface of an imaging element for color video images (C).

A video signal (Sf) of the images taken by the imaging element for color video images (C) is transmitted to a signal processing circuit (H′) in order to generate light quantity data (ShR′, ShG′, ShB′) of the respective R, G, and B wavelength bands.

The integrating control circuit (Mc) obtains the light quantity data (ShR′, ShG′, ShB′) and, at the same time, obtains the power values or the current values of the light emitting elements (Y1a, Y1b, . . . , Y2a, Y2b, . . . ) from the drive circuits (P1a, P1b, P2a, P2b, . . . ) to generate the light emission intensity instruction value correlated with light intensity and the estimated wavelength deviation instruction value correlated with deviation from reference wavelength, as described above. Further, the integrating control circuit (Mc) generates the color phase instruction value correlated with color of integrated light of the output luminous fluxes (Fo, Fo1, Fo2, . . . ) and performs feedback control such that a difference between the color phase instruction value and the target value thereof is reduced.

In addition, the integrating control circuit (Mc) separately measures the light quantity of each of the R-color exit ends (EoR I, EoR2, . . . ), the G-color exit ends (EoG1, EoG2, . . . ), and the B-color exit ends (EoB1 EoB2, . . . ) based on video images of the imaging element for color video images (C) and examines whether abnormality of light quantity reduction occurs in any of the exit ends to monitor breakage of optical fibers.

Hereinabove, there have been described

(1) the band light characteristics acquisition means (AiR) for measuring the light emission intensity instruction value correlated with light intensity and for measuring the wavelength deviation instruction value using the wavelength dispersibility optical element (Eg), (λ) band light characteristics acquisition means constituted of first light quantity measuring means (A1R, A1G, A1B) and second light quantity measuring means (A2R, A2G, A2B) different in the rate of sensitivity varying against wavelength varying and used for measuring the light emission intensity instruction value correlated with light intensity and for measuring the wavelength deviation instruction value,

(3) the band light characteristics acquisition means for estimating the wavelength deviation instruction value from the temperature of the light emitting element,

(4) the band light characteristics acquisition means for estimating the wavelength deviation instruction value from the power of the light emitting element, and

(5) the band light characteristics acquisition means for measuring the light emission intensity instruction value correlated with light intensity and for measuring the tristimulus values with the use of a light quantity detector in which in the spectral sensitivity characteristics, the sensitivity value at reference wavelength determined in the respective wavelength bands and the rate of sensitivity varying against wavelength varying match with the sensitivity value at reference wavelength of three color matching functions of an XYZ color system and the rate of sensitivity varying against wavelength varying. However, the band light characteristics acquisition means is not limited to those methods and configurations, and as described above, band light characteristics acquisition means having any configuration may be used in the light source device of the present invention as long as it can measure/obtain those quantities.

As the band light characteristics acquisition means (AiR, AiG, AiB) of the respective R, G, and B wavelength bands, the band light characteristics acquisition means all having the same method may be used, or the band light characteristics acquisition means having different methods depending on the wavelength band may be mixedly used.

Further, in the present invention, in the case where the light emitting element in which the wavelength variation does not substantially occur or is ignorable in any of the wavelength bands is included, for the wavelength band, the band light characteristics acquisition means may be used for obtaining only the light emission intensity instruction values correlated with light intensity. In such case, the calculation of the above-described (expression 8) to (expression 14) may be performed while the value corresponding to the wavelength band among the wavelength deviation instruction values Δλr, Δλg, and Δλb in the (expression 8) to (expression 14) is assumed to be 0.

Actually, in a semiconductor laser whose oscillation wavelength is stabilized, a semiconductor laser having a resonance reflector constituted of a volume Bragg diffraction grating, a non-linear optical harmonic oscillator, and the like, a light emitting element capable of being handled in such a way exists.

For example, in the case where the wavelength band is G color, an optical sensor having sensitivity for the G wavelength band may be provided to measure the light quantity of the output luminous flux for measurement (Fo′), and the obtained light emission intensity instruction value Sg and the wavelength deviation instruction value Δλg=0 may be applied to the (expression 8) to (expression 14).

Naturally, when it is considered that the wavelength variation does not substantially occur in all wavelength bands, or when, although the wavelength variation occurs, it is ignored, calculation may be performed by an expression in which the wavelength deviation instruction values Δλr, Δλg, and Δλb are all assumed to be 0.

In this specification, regarding the color phase correlation data (Se) obtained through processing inside the light source device and the interface section (If), the case where the chromaticity coordinates (Yxy color system) and the tristimulus values (XYZ color system) are used as the color phase instruction value correlated with color of light is referred and has been specifically described. However, even if color systems other than those color systems, such as an RGB color system, an Luv color system, or an Lab color system, is used, any value may be naturally adopted as long as it is the color phase instruction value correlated with the chromaticity coordinates.

### INDUSTRIAL APPLICABILITY

The present invention is applicable in industries designing and manufacturing light source devices usable in an optical apparatus such as a projector and using a light emitting element, such as a semiconductor laser, belonging to a plurality of types of different wavelength bands.

### DESCRIPTION OF REFERENCE SIGNS

A1B first light quantity measuring means
A1G first light quantity measuring means
A1R first light quantity measuring means
A2B second light quantity measuring means
A2G second light quantity measuring means
A2R second light quantity measuring means
Ae color phase instruction value measuring means
Ah1 optical sensor circuit section
Ah2 optical sensor circuit section
AiB band light characteristics acquisition means
AiG band light characteristics acquisition means
AiR band light characteristics acquisition means
Δx band light characteristics acquisition means set
Δx1 first light quantity measuring means group
Δx2 second light quantity measuring means group
B blue
C imaging element for color video images
C1B optical sensor
C1G optical sensor
C1R optical sensor
Ca imaging element
Cx smoothing capacitor
CX optical sensor
CY optical sensor
CZ optical sensor
DmjA two-dimensional optical amplitude modulation element
DmjB two-dimensional optical amplitude modulation element
Dx fly wheel diode
Ea pinhole
Eap aperture plate
Eb1 condenser lens
Eb2 collimator lens
Eb3 image forming lens
Ec1 focusing optical system
Ec2 focusing optical system
Edm diffusion element
Ef1 optical fiber
Ef2 optical fiber
EfB1 optical fiber for B light source
EfB2 optical fiber for B light source
EfG1 optical fiber for G light source
EfG2 optical fiber for G light source
EfR1 optical fiber for R light source
EfR2 optical fiber for R light source
Eg wavelength dispersibility optical element
Eh imaging optical system
Ei1 incident end
Ei2 incident end
Ej1A illumination lens
Ej1B illumination lens
Ej2A image projection lens
Ej2B field lens
Ej3B image projection lens
Eo1 exit end
Eo2 exit end
EoB1 B exit end
EoB2 B exit end
EoG1G exit end
EoG2 G exit end
EoR1 R exit end
EoR2 R exit end
EsB collimator lens
EsG collimator lens
EsR collimator lens
Et1 characteristics filter
Et1B band filter
Et1G band filter
Et1R band filter
Et2 characteristics filter
EtX characteristics filter
EtY characteristics filter
EtZ characteristics filter
Eu focusing lens
F1B front fly eye lens
F2B rear fly eye lens
Fm homogenizing means
FmA homogenizing means
FmB homogenizing means
Fo output luminous flux
Fo′ output luminous flux for measurement
Fo1 output luminous flux
Fo2 output luminous flux
FoR output luminous flux
FoR′ transmitted light
Ft1 output luminous flux for measurement
Ft1R output luminous flux for measurement
Ft1G output luminous flux for measurement
Ft1B output luminous flux for measurement
FtX output luminous flux for measurement
FtY output luminous flux for measurement
FtZ output luminous flux for measurement
Fx drive control circuit
G green
Gx gate drive circuit
H signal processing circuit
H′ signal processing circuit
H1B signal processing circuit
H1G signal processing circuit
H1R signal processing circuit
HsB signal processing circuit
HsG signal processing circuit
HsR signal processing circuit
HuB dichroic mirror
HuG dichroic mirror
HuR mirror
If interface section
Io output current
Ix output current detecting means
J1a drive circuit control signal
J1b drive circuit control signal
J2a drive circuit control signal
J2b drive circuit control signal
Lx choke coil
Mc integrating control circuit
MjA mirror
MjB polarization beam splitter
P1a drive circuit
P1b drive circuit
P2a drive circuit
P2b drive circuit
PcB polarization aligning function element
Pmi incident end
PmiA incident end
PmiB incident end
Pmo emission end
PmoA emission end
PmoB emission end
Qx switching element
R red
Se color phase correlation data
Sf video signal
Sg gate driving signal
Sg1B photodetection signal
Sg1G photodetection signal
Sg1R photodetection signal
SgX photodetection signal
SgY photodetection signal
SgZ photodetection signal
Sh1B first light quantity measurement data
Sh1G first light quantity measurement data
Sh1R first light quantity measurement data
Sh2B second light quantity measurement data
Sh2G second light quantity measurement data
Sh2R second light quantity measurement data
ShB band light characteristics acquisition data
ShB′ light quantity data
ShG band light characteristics acquisition data
ShG' light quantity data
ShR band light characteristics acquisition data
ShR′ light quantity data
Si output current signal
SjA light source
SjB light source
Sv output voltage signal
Sxy data
T10 node
T11 node
T20 node
T21 node
Tj screen
U1 elemental light source
U2 elemental light source
Uv DC power supply
Vo output voltage
Vx output voltage detecting means
W white color
Y1a light emitting element
Y1b light emitting element
Y2a light emitting element
Y2b light emitting element
ZiB incident optical axis

1. A light source device in which a unit comprising a light emitting element (Y1a, Y1b, . . . ) emitting light in a narrow wavelength band and a drive circuit (P1a, P1b, . . . ) driving the light emitting element (Y1a, Y1b, . . . ) is a single elemental light source (U1, U2, . . . ) and which has a plurality of the elemental light sources (U1, U2, . . . ) and an integrating control circuit (Mc) controlling the drive circuit (P1a, P1b, P2a, P2b, . . . ) and emits an output luminous flux (Fo, Fo1, Fo2, . . . ), obtained by gathering light emitted from the light emitting element (Y1a, Y1b, Y2a, Y2b, . . . ), to outside,
the light emitting element (Y1a, Y1b, Y2a, Y2b, . . . ) including light emitting elements whose emission wavelength belongs to a plurality of types of different wavelength bands,
the light source device further having band light characteristics acquisition means (AiR, AiG, AiB) for receiving light of a quantity correlated with a light quantity of an integrated output luminous flux (Fo, Fo1, Fo2, . . . ) of the output luminous flux (Fo, Fo1, Fo2, . . . ) to generate band light characteristics acquisition data (ShR, ShG, ShB) for obtaining a light emission intensity instruction value correlated with light intensity for each of the wavelength bands and an interface section (If) for obtaining data from outside,
the integrating control circuit (Mc) at least intermittently obtaining the band light characteristics acquisition data (ShR, ShG, ShB) generated by the band light characteristics acquisition means (AiR, AiG, AiB) to generate the light emission intensity instruction value and, at the same time, generating a color phase instruction value correlated with color of integrated light of the output luminous flux (Fo, Fo1, Fo2, . . . ) and determining variation of the light emission intensity instruction values for the respective wavelength bands to perform feedback control of the drive circuit (P1a, P1b, P2a, P2b, . . . ) such that a difference between the color phase instruction value and the target value thereof is reduced,
the integrating control circuit (Mc) further executing an external data acquisition mode in which color phase correlation data (Se) correlated with the color phase instruction value with respect to the result of applying the output luminous flux (Fo, Fo1, Fo2, . . . ) to an external apparatus using the light source device is obtained through the interface section (If), and the integrating control circuit (Mc) updating a target value of the color phase instruction value with the use of the color phase correlation data (Se) after termination of the external data acquisition mode.

2. The light source device according to claim 1, wherein a balance of light usage efficiency of an external apparatus using the light source device to each wavelength band is estimated by the color phase instruction value with respect to the result of applying the output luminous flux (Fo, Fo1, Fo2, . . . ) to an external apparatus using the light source device, the color phase instruction value being calculated from the color phase correlation data (Se) obtained by execution of the external data acquisition mode, and after the estimation of the balance of the light usage efficiency of the external apparatus, the target value of the color phase instruction value of the light source device is set such that the color phase instruction value relating to the result of applying the output luminous flux (Fo, Fo1, Fo2, . . . ) to the external apparatus using the light source device approaches the color phase instruction value desired.

3. The light source device according to claim 1, wherein the band light characteristics acquisition means (AiR, AiG, AiB) is configured to generate, in addition to the light emission intensity instruction value correlated with light intensity, the band light characteristics acquisition data (ShR, ShG, ShB) for obtaining a wavelength deviation instruction value correlated with deviation from reference wavelength for each of the wavelength bands, the integrating control circuit (Mc) obtains the band light characteristics acquisition data (ShR, ShG, ShB) from the band light characteristics acquisition means (AiR, AiG, AiB) to generate the wavelength deviation instruction value in addition to the light emission intensity instruction value, when generating the color phase instruction value, the integrating control circuit (Mc) holds, for each of the wavelength bands, local band color matching function information, including a function value in reference wavelength and the rate of function varying against wavelength varying, with respect to the color matching functions required for calculation of chromaticity and calculates the color phase instruction value by a quantity correlated with chromaticity coordinates with the use of the wavelength deviation instruction value and the local band color matching function information for each of the wavelength bands.

4. The light source device according to claim 1, wherein regarding spectral sensitivity characteristics of a light quantity detector provided for each of the wavelength bands for obtaining a light emission intensity instruction value correlated with light intensity in the band light characteristics acquisition means (AiR, AiG, AiB), a sensitivity value at reference wavelength determined in each of the wavelength bands and the rate of sensitivity varying against wavelength varying match with a sensitivity value at reference wavelength of three color matching functions of an XYZ color system and the rate of sensitivity varying against wavelength varying.

5. The light source device according to claim 3, wherein regarding spectral sensitivity characteristics of a light quantity detector provided for each of the wavelength bands for obtaining a light emission intensity instruction value correlated with light intensity in the band light characteristics acquisition means (AiR, AiG, AiB), a sensitivity value at reference wavelength determined in each of the wavelength bands and the rate of sensitivity varying against wavelength varying match with a sensitivity value at reference wavelength of three color matching functions of an XYZ color system and the rate of sensitivity varying against wavelength varying.

6. A projector projecting and displaying an image with the use of the light source device according to claim 1 any one of claims 1 to 5.

7. The light source device according to claim 2, wherein the band light characteristics acquisition means (AiR, AiG, AiB) is configured to generate, in addition to the light emission intensity instruction value correlated with light intensity, the band light characteristics acquisition data (ShR, ShG, ShB) for obtaining a wavelength deviation instruction value correlated with deviation from reference wavelength for each of the wavelength bands, the integrating control circuit (Mc) obtains the band light characteristics acquisition data (ShR, ShG, ShB) from the band light characteristics acquisition means (AiR, AiG, AiB) to generate the wavelength deviation instruction value in addition to the light emission intensity instruction value, when generating the color phase instruction value, the integrating control circuit (Mc) holds, for each of the wavelength bands, local band color matching function information, including a function value in reference wavelength and the rate of function varying against wavelength varying, with respect to the color matching functions required for calculation of chromaticity and calculates the color phase instruction value by a quantity correlated with chromaticity coordinates with the use of the wavelength deviation instruction value and the local band color matching function information for each of the wavelength bands.

8. The light source device according to claim 2, wherein regarding spectral sensitivity characteristics of a light quantity detector provided for each of the wavelength bands for obtaining a light emission intensity instruction value correlated with light intensity in the band light characteristics acquisition means (AiR, AiG, AiB), a sensitivity value at reference wavelength determined in each of the wavelength bands and the rate of sensitivity varying against wavelength varying match with a sensitivity value at reference wavelength of three color matching functions of an XYZ color system and the rate of sensitivity varying against wavelength varying.

9. The light source device according to claim 7, wherein regarding spectral sensitivity characteristics of a light quantity detector provided for each of the wavelength bands for obtaining a light emission intensity instruction value correlated with light intensity in the band light characteristics acquisition means (AiR, AiG, AiB), a sensitivity value at reference wavelength determined in each of the wavelength bands and the rate of sensitivity varying against wavelength varying match with a sensitivity value at reference wavelength of three color matching functions of an XYZ color system and the rate of sensitivity varying against wavelength varying.

10. A projector projecting and displaying an image with the use of the light source device according to claim 2.

11. A projector projecting and displaying an image with the use of the light source device according to claim 3.

12. A projector projecting and displaying an image with the use of the light source device according to claim 4.

13. A projector projecting and displaying an image with the use of the light source device according to claim 5.

14. A projector projecting and displaying an image with the use of the light source device according to claim 7.

15. A projector projecting and displaying an image with the use of the light source device according to claim 8.

16. A projector projecting and displaying an image with the use of the light source device according to claim 9.
